(19) United States
(12) Patent Application Publication
(10) Pub. No.: US 2025/0100076 A1
(43) Pub. Date: Mar. 27, 2025

(54) LASER APPARATUS, LASER SYSTEM, AND METHOD FOR MANUFACTURING ELECTRONIC DEVICES

(71) Applicant: Gigaphoton Inc., Tochigi (JP)

(72) Inventor: Natsushi SUZUKI, Oyama-shi (JP)

(73) Assignee: Gigaphoton Inc., Tochigi (JP)

(21) Appl. No.: 18/975,840

(22) Filed: Dec. 10, 2024

Related U.S. Application Data
(63) Continuation of application No. PCT/JP2022/028920, filed on Jul. 27, 2022.

(51) Int. Cl. B23K 26/12; B23K 26/70; B23K 101/36

(52) U.S. Cl. CPC B23K 26/125; B23K 26/702; B23K 2101/36

(57) ABSTRACT

A laser apparatus includes a laser chamber connected to a gas circulating system including a merging pipe where exhaust gases exhausted from multiple laser apparatuses merge with each other, and configured to select one of a fresh gas containing xenon and a circulating gas flowing through the merging pipe and supply the multiple laser apparatuses with the selected gas; an exhaust pipe which is connected to and between the laser chamber and the merging pipe, and through which the exhaust gas exhausted from the laser chamber flows toward the merging pipe; a fluorine trap connected to a halfway point of the exhaust pipe and configured to remove fluorine from the exhaust gas; and a xenon adder connected to a halfway point of the exhaust pipe and configured to add an additive gas having a xenon concentration higher than a xenon concentration in the fresh gas to the exhaust gas.

### CROSS-REFERENCE TO RELATED APPLICATIONS

The present application is a continuation application of International Application No. PCT/JP2022/028920, filed on Jul. 27, 2022, the entire contents of which are hereby incorporated by reference.

### BACKGROUND

### 1. Technical Field

The present disclosure relates to a laser apparatus, a laser system, and a method for manufacturing electronic devices.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses undergoing spontaneous laser oscillation has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon and grating) is provided in some cases in a laser resonator of the gas laser apparatus to narrow the spectral linewidth. A gas laser apparatus providing a narrowed spectral linewidth is referred to as a narrowed-line laser apparatus.

### CITATION LIST

### Patent Literature

[PTL 1] U.S. Patent application Publication No. 2020/0403371
[PTL 2] U.S. Patent application Publication No. 2016/0248215

### SUMMARY

A laser apparatus according to an aspect of the present disclosure includes a laser chamber connected to a gas circulating system including a merging pipe where exhaust gases exhausted from multiple laser apparatuses including the laser apparatus merge with each other, the gas circulating system being configured to select one of a fresh gas containing xenon and a circulating gas flowing through the merging pipe and supply the multiple laser apparatuses with the selected gas; an exhaust pipe which is connected to and between the laser chamber and the merging pipe, and through which the exhaust gas exhausted from the laser chamber flows toward the merging pipe; a fluorine trap connected to a halfway point of the exhaust pipe and configured to remove at least fluorine from the exhaust gas exhausted from the laser chamber; and a xenon adder connected to a halfway point of the exhaust pipe and configured to add an additive gas having a xenon concentration higher than a xenon concentration in the fresh gas to the exhaust gas exhausted from the laser chamber.

A laser system according to another aspect of the present disclosure includes multiple laser apparatuses; and a gas circulating system including a merging pipe where exhaust gases exhausted from the multiple laser apparatuses merge with each other, the gas circulating system being configured to select one of a fresh gas containing xenon and a circulating gas flowing through the merging pipe and supply the multiple laser apparatuses with the selected gas.

The multiple laser apparatuses each include a laser chamber connected to the gas circulating system, an exhaust pipe which is connected to and between the laser chamber and the merging pipe, and through which the exhaust gas exhausted from the laser chamber flows toward the merging pipe; a fluorine trap connected to a halfway point of the exhaust pipe and configured to remove at least fluorine from the exhaust gas exhausted from the laser chamber; and a xenon adder connected to a halfway point of the exhaust pipe and configured to add an additive gas having a xenon concentration higher than a xenon concentration in the fresh gas to the exhaust gas exhausted from the laser chamber.

A method for manufacturing electronic devices according to another aspect of the present disclosure includes generating laser light by using a laser apparatus that is one of multiple laser apparatuses, the laser apparatus including a laser chamber connected to a gas circulating system including a merging pipe where exhaust gases exhausted from the multiple laser apparatuses merge with each other, the gas circulating system being configured to select one of a fresh gas containing xenon and a circulating gas flowing through the merging pipe and supply the multiple laser apparatuses with the selected gas, an exhaust pipe which is connected to and between the laser chamber and the merging pipe, and through which the exhaust gas exhausted from the laser chamber flows toward the merging pipe, a fluorine trap connected to a halfway point of the exhaust pipe and configured to remove at least fluorine from the exhaust gas exhausted from the laser chamber, and a xenon adder connected to a halfway point of the exhaust pipe and configured to add an additive gas having a xenon concentration higher than a xenon concentration in the fresh gas to the exhaust gas exhausted from the laser chamber. The method for manufacturing electronic devices further includes outputting the laser light to an exposure apparatus, and exposing a photosensitive substrate to the laser light in the exposure apparatus to manufacture the electronic devices.

### BRIEF DESCRIPTION OF DRAWINGS

Embodiments of the present disclosure will be described below only by way of example with reference to the accompanying drawings.

FIG. 1 schematically shows the configuration of a laser system according to Comparative Example.

FIG. 2 shows an example of a fluorine concentration and a xenon concentration in a variety of gases in Comparative Example.

FIG. 3 shows an example of the fluorine concentration and the xenon concentration in the variety of gases in a case where a gas circulating system is connected to multiple laser chambers in Comparative Example.

FIG. 4 schematically shows the configuration of a laser system according to a first embodiment.

FIG. 5 is a flowchart showing an overview of gas control in a laser apparatus.

FIG. 6 schematically shows an initial gas supply operation.

FIG. 7 shows the result of the initial gas supply operation.

FIG. 8 schematically shows an n-th gas rinse operation.

FIG. 9 shows the result of a gas exhaust operation in the first gas rinse operation.

FIG. 10 shows the result of a gas supply operation in the first gas rinse operation.

FIG. 11 shows the result of the gas exhaust operation in the n-th gas rinse operation.

FIG. 12 shows the result of the gas supply operation in the n-th gas rinse operation.

FIG. 13 is a flowchart showing a xenon addition process in the first embodiment.

FIG. 14 is a flowchart showing the details of the control performed by a xenon adder.

FIG. 15 is a timing chart of the xenon addition process under the control of the xenon adder shown in FIG. 14.

FIG. 16 shows an example of changes over time in pulse energy of laser light output from the laser apparatus when a xenon concentration in a laser chamber falls within an optimum range.

FIG. 17 shows an example of changes over time in pulse energy of the laser light output from the laser apparatus when the xenon concentration in the laser chamber is outside the optimum range.

FIG. 18 shows an example of changes over time in pulse energy of the laser light output from the laser apparatus when the xenon concentration in the laser chamber is outside the optimum range by a greater degree.

FIG. 19 shows an example of a graph showing the relationship between a ratio Er and an estimated xenon concentration.

FIG. 20 shows changes over time in voltage having high-voltage pulses and applied to discharge electrodes in the laser apparatus in the case where the xenon concentration inside the laser chamber falls within the optimum range.

FIG. 21 shows changes over time in voltage having high-voltage pulses and applied to the discharge electrodes in the laser apparatus in the case where the xenon concentration inside the laser chamber is outside the optimum range.

FIG. 22 shows changes over time in voltage having high-voltage pulses and applied to the discharge electrodes in the laser apparatus in the case where the xenon concentration inside the laser chamber is outside the optimum range by a greater degree.

FIG. 23 shows an example of a graph showing the relationship between a ratio HVr and the estimated xenon concentration.

FIG. 24 schematically shows the configuration of a first variation of the first embodiment.

FIG. 25 schematically shows the configuration of a second variation of the first embodiment.

FIG. 26 is a flowchart showing a xenon addition process in a second embodiment.

FIG. 27 shows an example of a correction coefficient.

FIG. 28 schematically shows the configuration of a laser system according to a third embodiment.

FIG. 29 is a flowchart showing a xenon addition process in the third embodiment.

FIG. 30 is a flowchart showing how to update the correction coefficient in detail.

FIG. 31 shows an example of the correction coefficient before and after the update.

FIG. 32 schematically shows the configuration of a laser system according to a fourth embodiment.

FIG. 33 is a timing chart showing how a xenon concentration meter measures a measured xenon concentration in a regenerated inert gas.

FIG. 34 is a flowchart showing how to update the correction coefficient in the fourth embodiment.

FIG. 35 schematically shows the configuration of an exposure apparatus connected to the laser apparatus.

### DETAILED DESCRIPTION

### <Contents

1. Laser system according to Comparative Example
1.1 Configuration
1.1.1 Laser apparatuses 30a and 30b
1.1.2 Gas circulating system 50
1.2 Operation
1.2.1 Operation of laser apparatuses 30a and 30b
1.2.2 Operation of gas circulating system 50
1.3 Problems with Comparative Example
2. Laser apparatus 30a including xenon adder 60 in exhaust pipe 24a
2.1 Configuration
2.2 Calculation of Xe concentration in exhaust gas C(Xe_vent_n)
2.3 Xenon addition process
2.4 Calculation of Xe concentration in exhaust gas C(Xe)
2.5 Laser apparatus 30a including OSC laser chamber 101 and AMP laser chamber 102
2.6 Laser apparatus 30a including xenon adder 60 disposed outside enclosure
2.7 Effects
3. Laser apparatus 30a that corrects xenon concentration and calculates the amount of Xe to be added to the exhaust gas V(Xe_add_cy)
3.1 Xenon addition process
3.2 Effects
4. Laser apparatus 30a that updates correction coefficient α
4.1 Configuration
4.2 Xenon addition process
4.3 Updating correction coefficient α
4.4 Effects
5. Laser system that updates correction coefficient α by using measured xenon concentration C(Xe_mes) in regenerated inert gas
5.1 Configuration
5.2 Updating correction coefficient α
5.3 Effects
6. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Laser System According to Comparative Example

### 1.1 Configuration

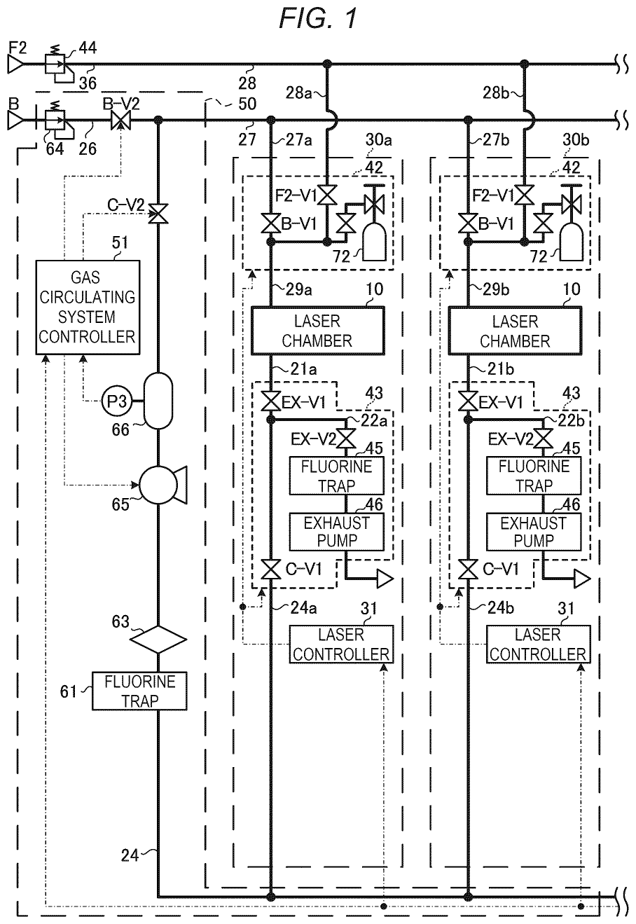

FIG. 1 schematically shows the configuration of a laser system according to Comparative Example. Comparative Example of the present disclosure is an aspect that the applicant is aware of as known only by the applicant, and is not a publicly known example that the applicant is self-aware of. The laser system includes multiple laser apparatuses 30a and 30b and a gas circulating system 50. The gas circulating system 50 is connected to each of the laser apparatuses 30a and 30b.

### 1.1.1 Laser Apparatuses 30a and 30b

The configuration of the laser apparatus 30a will be described with reference to FIG. 1. The configuration of the laser apparatus 30b is the same as that of the laser apparatus 30a except that the suffix of the reference character is changed from “a” to “b” in some cases.

The laser apparatus 30a includes a laser chamber 10, a laser controller 31, a gas supplier 42, and an exhauster 43. The laser apparatus 30a is an ArF excimer laser apparatus using a laser gas containing a fluorine gas and an argon gas.

The laser apparatus 30a is used, for example, along with an exposure apparatus that is not shown. Laser light output from the laser apparatus 30a enters the exposure apparatus. The exposure apparatus is configured to transmit a target pulse energy setting signal and a light emission trigger signal to the laser controller 31 provided in the laser apparatus 30a.

The laser controller 31 is configured to control the gas supplier 42 and the exhauster 43. The laser controller 31 is a processing apparatus including a memory that is not shown but stores a control program and a central processing unit (CPU) that is not shown but executes the control program, and the laser controller 31 corresponds to the processor in the present disclosure. The laser controller 31 is particularly configured or programmed to carry out a variety of processes described in the present disclosure.

The laser chamber 10 accommodates the laser gas and is disposed in the optical path of an optical resonator that is not shown. The laser chamber 10 accommodates a pair of discharge electrodes that are not shown. The discharge electrodes are connected to a high-voltage pulse power supply that is not shown.

The gas supplier 42 includes a portion of a pipe 28a connected to a fluorine-containing gas supplying pipe 28 and a portion of a pipe 29a connected to the laser chamber 10. Connecting the pipe 28a to the pipe 29a allows a fluorine-containing gas supply source F2 to supply the laser chamber 10 with a fluorine-containing gas.

The fluorine-containing gas supply source F2 is a gas cylinder that accommodates the fluorine-containing gas. The fluorine-containing gas is, for example, a laser gas that is a mixture of a fluorine gas, an argon gas, and a neon gas. The fluorine gas concentration in the fluorine-containing gas is adjusted to be higher than the fluorine gas concentration inside the laser chamber 10. The fluorine-containing gas may, for example, have the following gas composition ratio: the fluorine gas accounts for 1%; the argon gas accounts for 3.5%; and the neon gas accounts for the remainder. The pressure at which the laser gas is supplied from the fluorine-containing gas supply source F2 to the fluorine-containing gas supplying pipe 28 is set by a regulator 44 to a value, for example, greater than or equal to 5000 hPa but smaller than or equal to 6000 hPa.

The gas supplier 42 includes a valve F2-V1 provided in the pipe 28a. The operation of supplying the fluorine-containing gas from the fluorine-containing gas supply source F2 to the laser chamber 10 through the pipe 29a is controlled by opening and closing the valve F2-V1.

The gas supplier 42 further includes a portion of a pipe 27a connected to an inert gas pipe 27. Connecting the pipe 27a to the pipe 29a allows the gas circulating system 50 to supply the laser chamber 10 with an inert gas. The inert gas may be a fresh inert gas supplied from an inert gas supply source B, which will be described later, or a regenerated inert gas containing impurities reduced in the gas circulating system 50. The fresh inert gas corresponds to the fresh gas in the present disclosure, and the regenerated inert gas corresponds to the circulating gas in the present disclosure.

The gas supplier 42 includes a valve B-V1 provided in the pipe 27a. The operation of supplying the inert gas from the gas circulating system 50 to the laser chamber 10 through the pipe 29a is controlled by opening and closing the valve B-V1.

The gas supplier 42 further includes a xenon-containing gas cylinder 72, which adds xenon to the gases in the laser chamber 10. The xenon-containing gas cylinder 72 is connected to the pipe 29a through a pipe including a valve.

The xenon-containing gas cylinder 72 is a gas cylinder that accommodates an additive gas having a xenon gas concentration higher than the xenon gas concentration in the fresh inert gas supplied from the inert gas supply source B. The additive gas is a laser gas containing an argon gas and a neon gas with which a xenon gas is mixed. The additive gas may, for example, have the following gas composition ratio: the xenon gas accounts for 10000 ppm; the argon gas accounts for 3.5%; and the neon gas accounts for the remainder.

The exhauster 43 includes a portion of a pipe 21a connected to the laser chamber 10, and a portion of a pipe 22a connected, for example, to an exhaust treatment apparatus that is not shown but is external to the apparatus. Connecting the pipe 21a to the pipe 22a allows the exhaust gas exhausted from the laser chamber 10 to be exhausted out of the apparatus. In the present disclosure, the term “external to the apparatus, out of the apparatus, or outside” refers to a region or a unit that includes none of the laser apparatuses 30a and 30b and the gas circulating system 50. The term “unit” may, for example, be an exhaust duct that is not shown but is capable of exhausting the laser gas from which the fluorine gas has been removed. The exhaust duct may be connected to a scrubber that is not shown.

The exhauster 43 includes a valve EX-V1 provided in the pipe 21a. The operation of exhausting the exhaust gas from the laser chamber 10 to the pipe 22a or a pipe 24a is controlled by opening and closing the valve EX-V1.

The exhauster 43 includes a valve EX-V2, a fluorine trap 45, and an exhaust pump 46, all of which are provided in the pipe 22a. The valve EX-V2, the fluorine trap 45, and the exhaust pump 46 are arranged in this order from the laser chamber 10 side. The operation of exhausting the exhaust gas having passed through the valve EX-V1 out of the laser apparatus is controlled by opening and closing the valve EX-V2.

The fluorine trap 45 may have a configuration that is the same as that of a fluorine trap 61, which will be described later. Instead, since the exhaust gas having passed through the fluorine trap 45 is not intended to be reused as the laser gas, the fluorine trap 45 may be configured to produce other by-products when removing fluorine.

The exhaust pump 46 is configured to forcibly exhaust the laser gas in the laser chamber 10 in such a way that the pressure in the laser chamber 10 becomes lower than or equal to the atmospheric pressure when the valves EX-V1 and EX-V2 are open.

The exhauster 43 further includes a portion of the exhaust pipe 24a. The exhaust pipe 24a is connected to a point between a merging pipe 24 of the gas circulating system 50 and the portion where the pipe 21a and the pipe 22a are connected to each other. Connecting the exhaust pipe 24a to the portion where the pipe 21a and the pipe 22a are connected to each other allows the exhaust gas exhausted from the laser chamber 10 to be supplied to the gas circulating system 50. The exhauster 43 includes a valve C-V1 provided in the exhaust pipe 24a. The operation of supplying the exhaust gas having passed through the valve EX-V1 to the gas circulating system 50 is controlled by opening and closing the valve C-V1. The operation of opening and closing the valves F2-V1, B-V1, EX-V1, EX-V2, and C-V1 and the operation of the exhaust pump 46 are controlled by the laser controller 31.

### 1.1.2 Gas Circulating System 50

The gas circulating system 50 includes a gas circulating system controller 51, the merging pipe 24, and a portion of the inert gas pipe 27. The merging pipe 24 is connected to the exhaust pipe 24a and an exhaust pipe 24b. The inert gas pipe 27 is connected to the pipe 27a and a pipe 27b.

In the gas circulating system 50, the fluorine trap 61, a filter 63, a booster pump 65, and a booster tank 66 are arranged in this order in the merging pipe 24 from the exhauster 43 side.

The gas circulating system 50 further includes a portion of a fresh inert gas pipe 26 connected to the inert gas supply source B. The fresh inert gas pipe 26 is connected to the portion where the merging pipe 24 and the inert gas pipe 27 are connected to each other. The inert gas supply source B is, for example, a gas cylinder that accommodates an inert gas containing an argon gas, a neon gas, and a small amount of xenon gas. The xenon gas concentration in the inert gas supply source B is adjusted to a value slightly higher than a target xenon gas concentration in the laser chamber 10. The inert gas in the inert gas supply source B may, for example, have the following gas composition ratio: the xenon gas accounts for 10 ppm; the argon gas accounts for 3.5%; and the neon gas accounts for the remainder. In the present disclosure, the inert gas having been supplied from the inert gas supply source B but not having yet reached the laser chamber 10 may be referred to as a fresh inert gas to distinguish it from the regenerated inert gas supplied from the merging pipe 24. The pressure at which the fresh inert gas is supplied from the inert gas supply source B to the fresh inert gas pipe 26 is set by a regulator 64 to a value, for example, greater than or equal to 5000 hPa but smaller than or equal to 6000 hPa. The gas circulating system 50 includes a valve B-V2 provided in the fresh inert gas pipe 26.

The fluorine trap 61 contains a treatment agent that traps the fluorine gas and fluorine compounds contained in the exhaust gas exhausted from the laser chamber 10. The treatment agent, which traps the fluorine gas and fluorine compounds, contains, for example, calcium hydroxide and zeolites. In this case, the fluorine gas reacts with the calcium hydroxide to produce calcium fluoride, water vapor, and oxygen gas. The calcium fluoride and water vapor are adsorbed by the zeolite. The oxygen gas is trapped by an oxygen trap that is not shown but is located downstream from the fluorine trap 61.

The fluorine trap 61 is not limited to the configuration described above, and only needs to remove at least the fluorine gas and fluorine compounds.

The filter 63 includes, for example, a mechanical filter that traps particles contained in the exhaust gas having passed through the fluorine trap 61, and an impurity gas trap that reduces impurity gases contained in the exhaust gas.

The booster pump 65 is a pump that boosts the pressure of the exhaust gas having passed through the filter 63 and supplies the resultant gas to the booster tank 66. The booster pump 65 is configured, for example, with a diaphragm-type or bellows-type pump that allows only a small amount of oil to be mixed with the exhaust gas.

The booster tank 66 is a container that accommodates the regenerated inert gas having passed through the booster pump 65. A boosted pressure sensor P3 is attached to the booster tank 66.

The gas circulating system controller 51 is configured to transmit and receive signals to and from the laser controller 31 and control each element of the gas circulating system 50. The gas circulating system controller 51 is a processing apparatus including a memory that is not shown but stores a control program, and a CPU that is not shown but executes the control program, and the gas circulating system controller 51 corresponds to the processor in the present disclosure. The gas circulating system controller 51 is particularly configured or programmed to carry out a variety of processes described in the present disclosure.

### 1.2 Operation

### 1.2.1 Operation of Laser Apparatuses 30a and 30b

In each of the laser apparatuses 30a and 30b, the laser controller 31 receives the target pulse energy setting signal and the light emission trigger signal from the exposure apparatus. The laser controller 31 transmits a control signal and a trigger signal to the high-voltage pulse power supply based on the target pulse energy setting signal and the light emission trigger signal received from the exposure apparatus.

The high-voltage pulse power supply generates a pulse-shaped high voltage based on the control signal and the trigger signal received from the laser controller 31. The high voltage is applied to the pair of discharge electrodes. Discharge thus occurs between the discharge electrodes. The energy of the discharge excites the laser gas in the laser chamber 10, and the excited laser gas transitions to a high energy level. Thereafter, when the excited laser gas transitions to a low energy level, the laser gas emits light having a wavelength according to the difference between the energy levels.

The light generated in the laser chamber 10 travels back and forth in the optical resonator, and is amplified whenever the light passes through the discharge space between the discharge electrodes, resulting in laser oscillation. The thus amplified light is output as laser light via one mirror of the optical resonator.

### 1.2.2 Operation of Gas Circulating System 50

The gas circulating system 50 reduces impurities from the exhaust gas exhausted from the laser apparatuses 30a and 30b. The gas circulating system 50 supplies the regenerated inert gas with reduced impurities to the laser apparatuses 30a and 30b.

The operation of supplying the regenerated inert gas from the merging pipe 24 to the inert gas pipe 27 is controlled by opening and closing a valve C-V2.

The operation of supplying the fresh inert gas from the inert gas supply source B to the inert gas pipe 27 is controlled by opening and closing the valve B-V2. The operation of opening and closing the valves C-V2 and B-V2 is controlled by the gas circulating system controller 51.

The gas circulating system controller 51 selects whether to close the valve C-V2 and open the valve B-V2, or to close the valve B-V2 and open the valve C-V2 to control the valves.

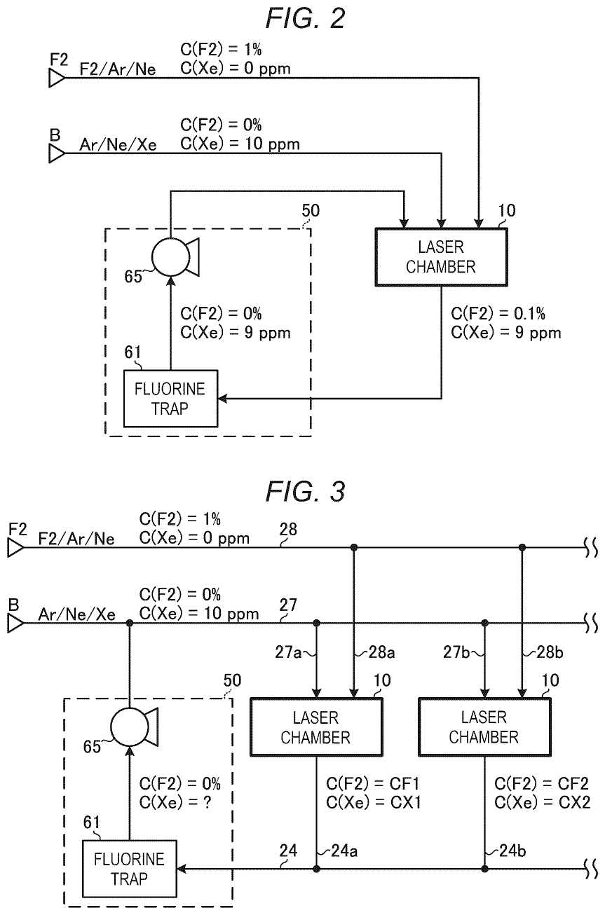

FIG. 2 shows an example of a fluorine concentration C(F2) and a xenon concentration C(Xe) of the variety of gases in Comparative Example. In FIG. 2, the fluorine-containing gas supplied from the fluorine-containing gas supply source F2 is a mixed gas that is a mixture of fluorine, argon, and neon with the fluorine concentration C(F2) being 1% and the xenon concentration C(Xe) being 0 ppm. The fresh inert gas supplied from the inert gas supply source B is a mixed gas that is a mixture of argon, neon, and xenon with the fluorine concentration C(F2) being 0% and the xenon concentration C(Xe) being 10 ppm. The reason why the xenon concentration C(Xe) in the fluorine-containing gas is set to 0 ppm and the fluorine concentration C(F2) in the fresh inert gas is set to 0% is to suppress the reaction between fluorine and xenon in the fluorine-containing gas supply source F2 and the inert gas supply source B.

To set the fluorine concentration C(F2) in the gases in the laser chamber 10 to 0.1% and the xenon concentration C(Xe) therein to 9 ppm, the ratio at which the fluorine-containing gas and the fresh inert gas are mixed with each other may be set to 1:9. When the exhaust gas exhausted from the laser chamber 10 is introduced into the gas circulating system 50 to regenerate the exhaust gas, the exhaust gas passes through the fluorine trap 61, and the fluorine concentration C(F2) of the resultant exhaust gas becomes 0%. The xenon concentration C(Xe) of the exhaust gas remains at 9 ppm.

The regenerated inert gas having passed through the gas circulating system 50 does not contain fluorine. Therefore, when the regenerated inert gas is returned to the laser chamber 10, fresh fluorine-containing gas is also supplied to the laser chamber 10 along with the regenerated inert gas. If the regenerated inert gas to which no xenon is added is returned to the laser chamber 10, the xenon concentration C(Xe) in the gas inside the laser chamber 10 becomes lower than 9 ppm because the regenerated inert gas is mixed with the fluorine-containing gas. Repeated regeneration of the exhaust gas keeps lowering the xenon concentration C(Xe) in the gas inside the laser chamber 10. To avoid the situation described above, xenon is added to the regenerated inert gas. Adjusting the amount of xenon to be added to return the xenon concentration C(Xe) in the regenerated inert gas to 10 ppm allows the gas composition of the regenerated inert gas to be substantially comparable to that of the fresh inert gas.

1.3 Problems with Comparative Example

FIG. 3 shows an example of the fluorine concentration C(F2) and the xenon concentration C(Xe) of the variety of gases in the case where the gas circulating system 50 is connected to multiple laser chambers 10 in Comparative Example. FIG. 2 shows the case where the fluorine concentration C(F2) of the gases in the laser chamber 10 is 0.1% and the xenon concentration C(Xe) therein is 9 ppm, and the concentrations are controlled to be different values in accordance with the states of the laser apparatuses 30a and 30b and the characteristics required therefor. For example, when it is necessary to increase the fluorine concentration C(F2) in the gases inside one laser chamber 10, the amount of fluorine-containing gas to be supplied to the laser chamber 10 may be increased. The mixing ratio of the fresh inert gas or the regenerated inert gas to the fluorine-containing gas then decreases, and the xenon concentration C(Xe) inside the laser chamber 10 therefore decreases.

As described above, the exhaust gases exhausted from the multiple laser chambers 10 may differ from one another not only in terms of fluorine concentration C(F2) but also in terms of xenon concentration C(Xe). When the exhaust gases are introduced into the gas circulating system 50, the exhaust gases pass through the fluorine trap 61, and the fluorine concentrations C(F2) of the exhaust gases become 0%. The xenon concentrations C(Xe), however, vary among the laser chambers 10, which exhaust the exhaust gases. If the xenon concentration C(Xe) in any of the exhaust gases cannot be determined, the amount of xenon to be added cannot be determined, and it may be difficult to return the xenon concentration C(Xe) in the regenerated inert gas to 10 ppm.

### 2. Laser Apparatus 30a Including Xenon Adder 60 in Exhaust Pipe 24a

### 2.1 Configuration

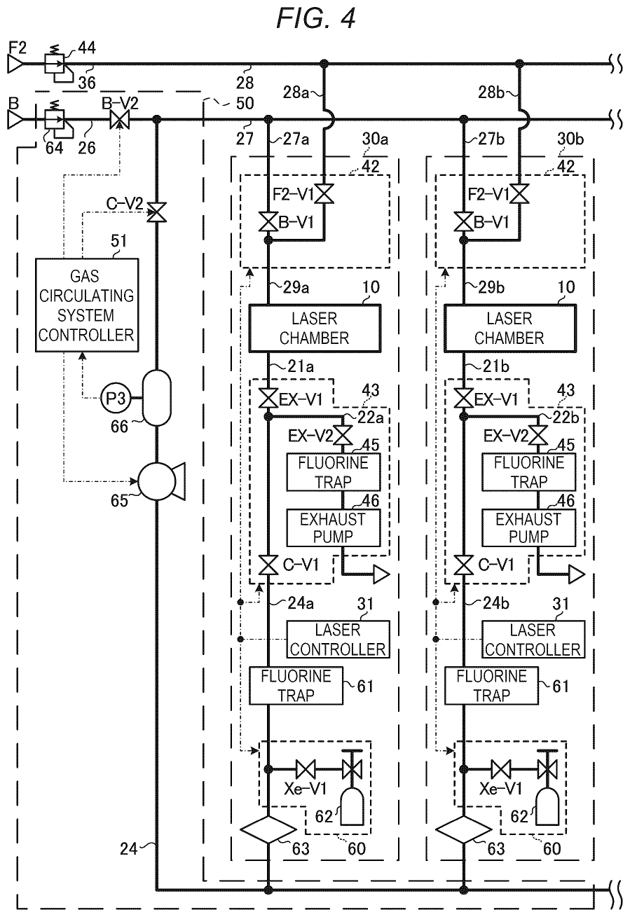

FIG. 4 schematically shows the configuration of a laser system according to a first embodiment. In the first embodiment, the gas supplier 42 may not include the xenon-containing gas cylinder 72. A xenon adder 60 is instead disposed in each of the exhaust pipes 24a and 24b. The xenon adder 60 disposed in the exhaust pipe 24b is the same as that disposed in the exhaust pipe 24a.

The xenon adder 60 includes a xenon-containing gas cylinder 62, which adds xenon to the exhaust gas. The xenon-containing gas cylinder 62 is connected to a halfway point of the exhaust pipe 24a via a pipe including a valve Xe-V1. The xenon-containing gas cylinder 62 is the same as the xenon-containing gas cylinder 72 described in Comparative Example.

It is desirable to place a regulator that is not shown between the xenon-containing gas cylinder 62 and the valve Xe-V1, the regulator keeping the pressure of the xenon-containing gas at the secondary side of the regulator that is close to the valve Xe-V1 constant. It is desirable to place an orifice that limits the flow rate of the additive gas between the regulator and the valve Xe-V1.

The xenon adder 60 is disposed between the valve EX-V1 and the merging point where the exhaust pipe 24a merges with the merging pipe 24.

The configuration in which the xenon adder 60 is disposed downstream from the valve EX-V1 in the flow of the exhaust gas causes the gas pressure of the exhaust gas to which xenon is added to be lower than the gas pressure in the laser chamber 10. Therefore, even when the xenon-containing gas cylinder 62 has a small amount of remainder so that the cylinder pressure drops, the additive gas can be supplied.

The configuration in which the xenon adder 60 is disposed upstream in the flow of the exhaust gas from the merging point where the exhaust pipe 24a merges with the merging pipe 24 allows a desired amount of xenon to be added to the exhaust gas from the laser apparatus 30a before the exhaust gas merges with the exhaust gas exhausted from the other laser apparatus 30b.

The operation of adding xenon from the xenon-containing gas cylinder 62 to the exhaust gas is controlled by opening and closing the valve Xe-V1. The operation of opening and closing the valve Xe-V1 is controlled by the laser controller 31.

It is desirable to place the fluorine trap 61 in the exhaust pipe 24a between the laser chamber 10 and the xenon adder 60. The fluorine trap 61 may not be placed in the gas circulating system 50.

The fluorine trap 61 may remove part of the xenon contained in the exhaust gas. When xenon is added to the exhaust gas before the exhaust gas passes through the fluorine trap 61, it may be necessary to add extra xenon in consideration of the amount of xenon removed by the fluorine trap 61. In contrast, the amount of xenon to be added can be suppressed by placing the xenon adder 60 downstream from the fluorine trap 61 and adding xenon to the exhaust gas having passed through the fluorine trap 61.

The filter 63 may be disposed in the exhaust pipe 24a of the laser apparatus 30a, or in the merging pipe 24 of the gas circulating system 50 as in Comparative Example. It is desirable to place the filter 63 downstream from the xenon adder 60. The filter 63 is made of a porous material, and a large number of pores contained in the porous material form a large number of gas flow channel branching points and merging points. When the exhaust gas and the additive gas pass through the filter 63, the two gases repeatedly undergo branching and merging, which promotes the exhaust gas and the additive gas to be mixed with each other.

### 2.2 Calculation of Xe Concentration in Exhaust Gas C(Xe_Vent_n)

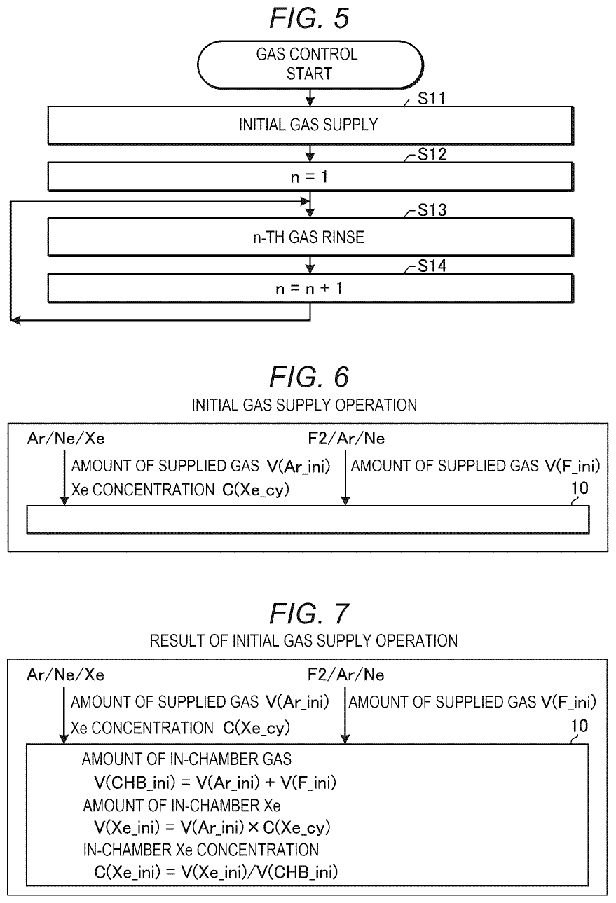

To add an appropriate amount of xenon to the exhaust gas exhausted from the laser chamber 10, it is desirable to determine the xenon concentration in the exhaust gas. The calculation of a Xe concentration in the exhaust gas C(Xe_vent_n) will be described with reference to FIGS. 5 to 12. The Xe concentration in the exhaust gas C(Xe_vent_n) is an example of a calculated xenon concentration in the present disclosure.

FIG. 5 is a flowchart showing an overview of gas control in the laser apparatus 30a.

In an initial gas supply step in S11, a fluorine-containing gas and an inert gas are supplied into the laser chamber 10 so exhausted that the pressure therein becomes lower than or equal to the atmospheric pressure. The gas composition inside the laser chamber 10 is thus initially adjusted, so that the laser apparatus 30a can output the laser light.

When the laser light is output, impurities are produced inside the laser chamber 10, and the amount of impurities increases over time, which may cause deterioration of the laser performance. To avoid the deterioration, part of the gas inside the laser chamber 10 is replaced with a clean gas. This operation is called gas rinse.

In S12, the value of a counter n indicating the number of times the gas rinse is performed is set to one.

In S13, the n-th gas rinse is performed.

In S14, the value of the counter n is incremented by one, so that the value of the counter n is updated. After S14, the gas control returns to S13, and the value of the counter n is updated in S14 whenever the n-th gas rinse is performed.

The Xe concentration in the exhaust gas C(Xe_vent_n) is a xenon concentration calculated from the entire history of the amounts of supplied and exhausted gas in the initial gas supply step and the first to n-th gas rinse steps described above.

FIG. 6 schematically shows an initial gas supply operation. In the initial gas supply operation, the amount of supplied fluorine-containing gas V(F_ini), the amount of supplied inert gas V(Ar_ini), and a xenon concentration in the inert gas C(Xe_cy) are all given from control data on the gas control in the laser apparatus 30a. It is assumed that the xenon concentration in the regenerated inert gas is adjusted to be equal to that of the fresh inert gas, and no distinction is made between the regenerated inert gas and the fresh inert gas in FIGS. 6 to 12.

FIG. 7 shows the result of the initial gas supply operation.

The amount of in-chamber gas V(CHB_ini) can be calculated by summing the amount of supplied fluorine-containing gas V(F_ini) and the amount of supplied inert gas V(Ar_ini) as follows:

$$V ( CHB\_ini ) = V ( Ar\_ini ) + V ( F\_ini )$$

The amount of in-chamber Xe V(Xe_ini) can be calculated by multiplying the amount of supplied inert gas V(Ar_ini) by the xenon concentration in the inert gas C(Xe_cy) as follows:

$$V ( Xe\_ini ) = V ( Ar\_ini ) \times C ( Xe\_cy )$$

An in-chamber Xe concentration C(Xe_ini) can be calculated by dividing the amount of in-chamber Xe V(Xe_ini) by the amount of in-chamber gas V(CHB_ini) as follows:

$$C ( Xe\_ini ) = V ( Xe\_ini ) / V ( CHB\_ini )$$

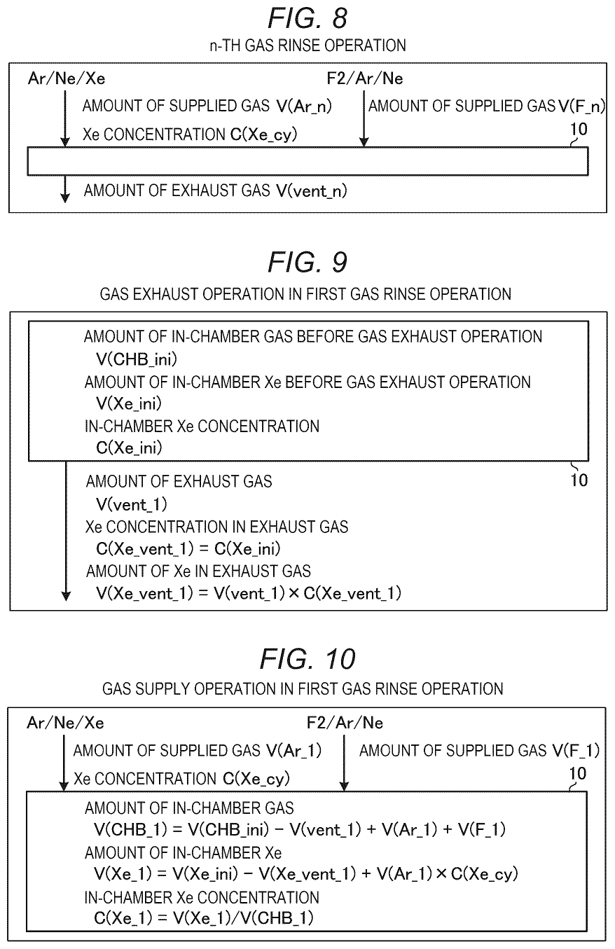

FIG. 8 schematically shows an n-th gas rinse operation. The gas rinse operation includes a gas exhaust operation and a gas supply operation, and replaces part of the gas inside the laser chamber 10. In the n-th gas rinse operation, the amount of supplied fluorine-containing gas V(F_n), the amount of supplied inert gas V(Ar_n), the xenon concentration in the inert gas C(Xe_cy), and the amount of exhaust gas V(vent_n) are all given from the control data on the gas control in the laser apparatus 30a.

FIG. 9 shows the result of a gas exhaust operation in the first gas rinse operation. The amount of in-chamber gas, the amount of in-chamber Xe, and the in-chamber Xe concentration before the gas exhaust operation in the first gas rinse operation are all given from the result of the initial gas supply operation (see FIG. 7).

The amount of exhaust gas V(vent_1) in the first gas rinse operation is given as the amount of exhaust gas V(vent_n) in the case where the value of the counter n is one (see FIG. 8).

A xenon concentration in the exhaust gas C(Xe_vent_1) is equal to the in-chamber Xe concentration C(Xe_ini) before the gas exhaust operation.

The amount of Xe in the exhaust gas V(Xe_vent_1) can be calculated by multiplying the amount of exhaust gas V(vent_1) by the xenon concentration in the exhaust gas C(Xe_vent_1) as follows:

$$V ( {Xe\_vent}_{-} 1 ) = V ( vent\_ 1 ) \times C ( {Xe\_vent}_{-} 1 )$$

FIG. 10 shows the result of a gas supply operation in the first gas rinse operation.

The amount of supplied fluorine-containing gas V(F_1) and the amount of supplied inert gas V(Ar_1) in the first gas rinse operation are given as the amount of supplied fluorine-containing gas V(F_n) and the amount of supplied inert gas V(Ar_n) in the case where the value of the counter n is one (see FIG. 8).

The amount of in-chamber gas V(CHB_1) can be calculated as follows by adding the amount of supplied fluorine-containing gas V(F_1) and the amount of supplied inert gas V(Ar_1) to a value obtained by subtracting the amount of exhaust gas V(vent_1) from the amount of in-chamber gas before the gas exhaust operation.

$$V ( CHB\_ 1 ) = V ( CHB\_ini ) - V ( vent\_ 1 ) + V ( Ar\_ 1 ) + V ( F\_ 1 )$$

The amount of in-chamber Xe V(Xe_1) can be calculated as follows by adding the value obtained by multiplying the amount of supplied inert gas V(Ar_1) by the xenon concentration in the inert gas C(Xe_cy) to the value obtained by subtracting the amount of Xe in the exhaust gas V(Xe_vent_1) from the amount of in-chamber Xe before the gas exhaust operation.

$$V ( Xe\_ 1 ) = V ( Xe\_ini ) - V ( Xe\_vent \_ 1 ) + V ( Ar\_ 1 ) \times C ( Xe\_cy )$$

An in-chamber Xe concentration C(Xe_1) can be calculated by dividing the amount of in-chamber Xe V(Xe_1) by the amount of in-chamber gas V(CHB_1) as follows:

$$C ( Xe\_ 1 ) = V ( Xe\_ 1 ) / V ( CHB\_ 1 )$$

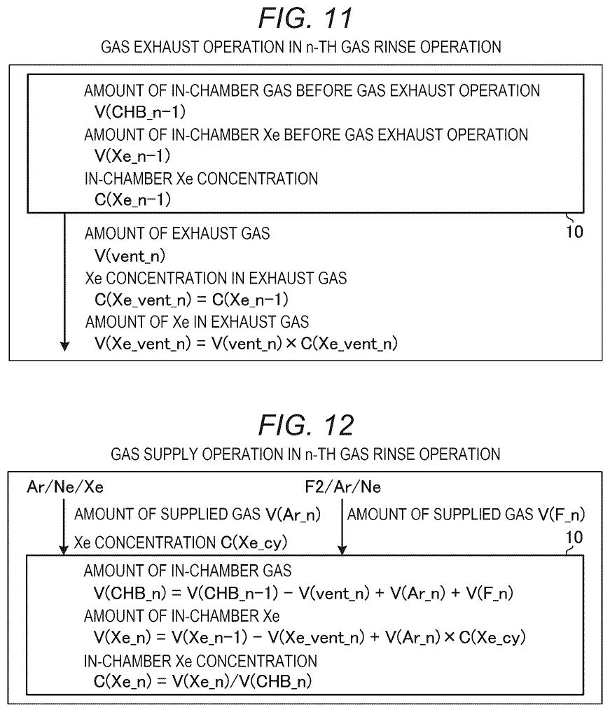

FIG. 11 shows the result of the gas exhaust operation in the n-th gas rinse operation, and FIG. 12 shows the result of the gas supply operation in the n-th gas rinse operation. The result of the n-th gas rinse operation can be determined by using the result of the (n−1)-th gas rinse operation. That is, the result of the first gas rinse operation can be used to determine the result of the second gas rinse operation, and the result of any n-th gas rinse operation can then be determined with n incremented by one.

The specific calculation expressions are the same as those shown in FIGS. 9 and 10 except that the suffix “_ini”, which indicates that the suffix is a parameter for the initial gas supply operation, is replaced with a suffix “_n−1”, and the suffix “_1”, which indicates that the suffix is a parameter for the first gas rinse operation, is replaced with a suffix “n” in FIGS. 9 and 10, so that the specific calculation expressions will not be described.

The procedure described above allows calculation of the Xe concentration in the exhaust gas C(Xe_vent_n) in any n-th gas rinse operation (see FIG. 11).

### 2.3 Xenon Addition Process

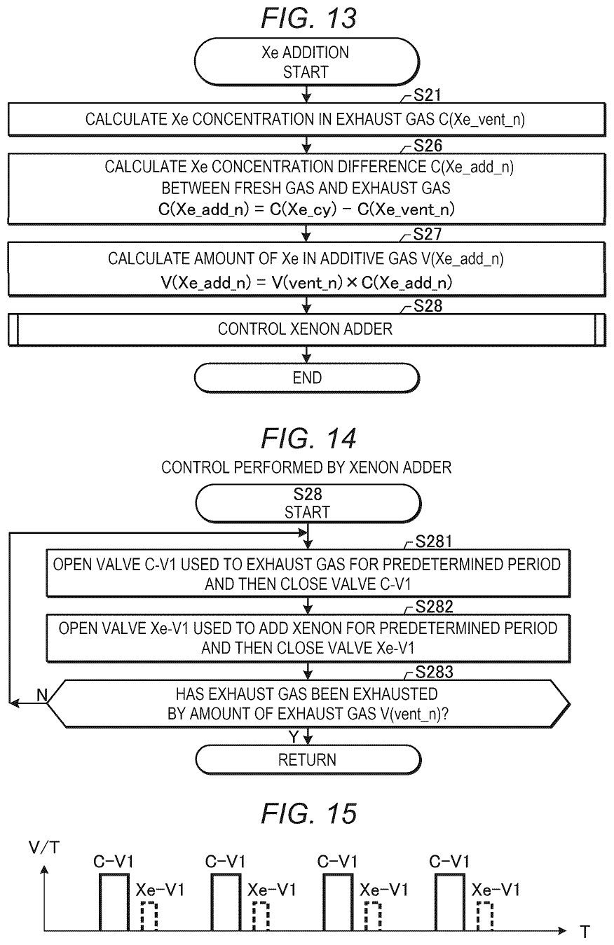

FIG. 13 is a flowchart showing a xenon addition process in the first embodiment. The processes shown in FIG. 13 are carried out by the laser controller 31.

In S21, the laser controller 31 calculates the Xe concentration in the exhaust gas C(Xe_vent_n) by using the method described with reference to FIGS. 6 to 12.

In S26, the laser controller 31 uses the following expression to calculate a xenon concentration difference C(Xe_add_n) between the xenon concentration in the fresh inert gas C(Xe_cy) supplied from the inert gas supply source B and the Xe concentration in the exhaust gas C(Xe_vent_n) exhausted from the laser chamber 10.

$$C ( Xe\_add \_n ) = C ( Xe\_cy ) - C ( Xe\_vent \_n )$$

In S27, the laser controller 31 calculates the amount of xenon in the additive gas V(Xe_add_n) by using the following expression in such a way that the xenon concentration in the exhaust gas having the amount of exhaust gas V(vent_n) approaches the xenon concentration C(Xe_cy) in the fresh inert gas.

$$V ( Xe\_add \_n ) = V ( vent\_n ) \times C ( Xe\_add \_n )$$

In S28, the laser controller 31 controls the xenon adder 60 to add the additive gas containing the amount of xenon in the additive gas V(Xe_add_n) to the exhaust gas. S28 will be described in detail with reference to FIGS. 14 and 15.

After step S28, the laser controller 31 terminates the processes in the present flowchart.

The laser controller 31 may carry out the process in S28 after converting the amount of xenon in the additive gas V(Xe_add_n) into the amount of the additive gas to be added to the exhaust gas V(Xe_add_cy) by using the following expression:

$$V ( Xe\_add \_cy ) = V ( Xe\_add \_n ) \times C ( Xe\_add \_cy )$$

where C(Xe_add_cy) is the xenon gas concentration in the xenon-containing gas cylinder 62.

FIG. 14 is a flowchart showing the details of the control performed by the xenon adder 60. The processes shown in FIG. 14 correspond to the subroutine S28 in FIG. 13. In the flowcharts in the present disclosure, “Y” at a branching point indicates the destination in a case where the result of the evaluation is YES, and “N” indicates the destination in a case where the result of the evaluation is NO.

In S281, the laser controller 31 opens the valve C-V1 of the exhauster 43 for a predetermined period and then closes the valve C-V1. The predetermined period is a period during which the operation of opening and closing the valve C-V1 once causes an amount of exhaust gas smaller than or equal to half, preferably one-fifth, of the amount of exhaust gas V(vent_n) to pass through the valve C-V1, and is, for example, several seconds.

In S282, the laser controller 31 opens the valve Xe-V1 of the xenon adder 60 for a predetermined period and then closes the valve Xe-V1. The predetermined period is a period during which the operation of opening and closing the valve Xe-V1 once causes an amount of additive gas smaller than or equal to half, preferably one-fifth, of the amount of additive gas to be added to the exhaust gas V(Xe_add_cy) to pass through the valve Xe-V1, and is, for example, about one second. It is desirable that the ratio of the amount of exhaust gas passing through the valve C-V1 during the operation of opening and closing the valve C-V1 once to the amount of additive gas passing through the valve Xe-V1 during the operation of opening and closing the valve Xe-V1 once be equal to the ratio at which the exhaust gas and the additive gas are mixed with each other.

In S283, the laser controller 31 evaluates whether the exhaust gas has been discharged by the amount of exhaust gas V(vent_n). When the exhaust gas has been discharged by the amount of exhaust gas V(vent_n) (YES in S283), the laser controller 31 terminates the processes in the present flowchart and returns to the processes shown in FIG. 13. When the exhaust gas has not been discharged by the amount of exhaust gas V(vent_n) (NO in S283), the laser controller 31 returns to the process in S281.

FIG. 15 is a timing chart of the xenon addition process under the control of the xenon adder 60 shown in FIG. 14. In FIG. 15, the horizontal axis represents time T, and the vertical axis represents the amount of gas passing through the valve C-V1 or Xe-V1 per unit time V/T.

The exhaust gas and the additive gas can be mixed with each other in the pipe by alternately opening the valves C-V1 and Xe-V1 each for a predetermined period, as shown in FIGS. 14 and 15. The valve C-V1 corresponds to the third valve in the present disclosure.

### 2.4 Calculation of Xe Concentration in Exhaust Gas C(Xe)

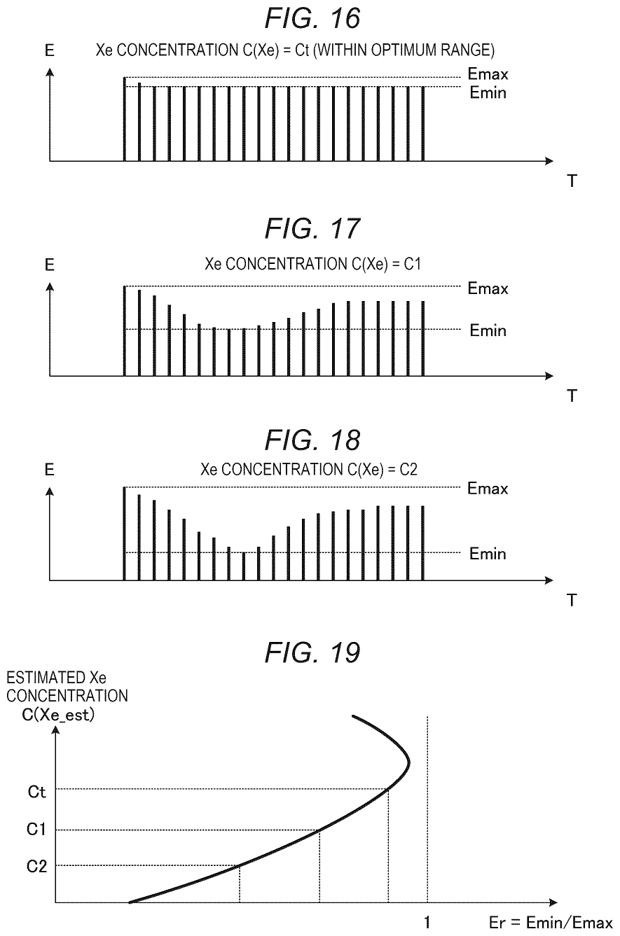

A first method for calculating an estimated xenon concentration C(Xe_est) from the laser performance will be described with reference to FIGS. 16 to 19. In S21 in FIG. 13, the estimated xenon concentration C(Xe_est) calculated by the first method may be used in place of the Xe concentration in the exhaust gas C(Xe_vent_n) described with reference to FIGS. 6 to 12. The estimated xenon concentration C(Xe_est) is an example of the calculated xenon concentration in the present disclosure.

FIGS. 16 to 18 show examples of changes over time Tin pulse energy E of the laser light output from the laser apparatus 30a. The laser apparatus 30a outputs pulse-shaped laser light at a predetermined repetition frequency for a predetermined period. In this process, the stability of the pulse energy E within the predetermined period described above may change in accordance with the state of the laser apparatus 30a.

FIG. 16 shows the pulse energy E in a case where a xenon concentration Ct inside the laser chamber 10 falls within an optimum range. A ratio Er of a minimum value Emin of the pulse energy E to a maximum value Emax thereof within the predetermined period described above is close to 1, which means that the pulse energy E is stable.

FIG. 17 shows the pulse energy E in a case where a xenon concentration C1 inside the laser chamber 10 is outside the optimum range. The ratio Er of the minimum value Emin of the pulse energy E to the maximum value Emax thereof within the predetermined period described above is decreased.

FIG. 18 shows the pulse energy E in a case where a xenon concentration C2 inside the laser chamber 10 is outside the optimum range by a greater degree. The ratio Er of the minimum value Emin of the pulse energy E to the maximum value Emax thereof within the predetermined period described above is further decreased.

FIG. 19 shows an example of a graph showing the relationship between the ratio Er and the estimated xenon concentration C(Xe_est). When there is a fixed relationship between the ratio Er and the xenon concentration inside the laser chamber 10, as shown in FIG. 19, the estimated xenon concentration C(Xe_est) can be calculated based on the relationship.

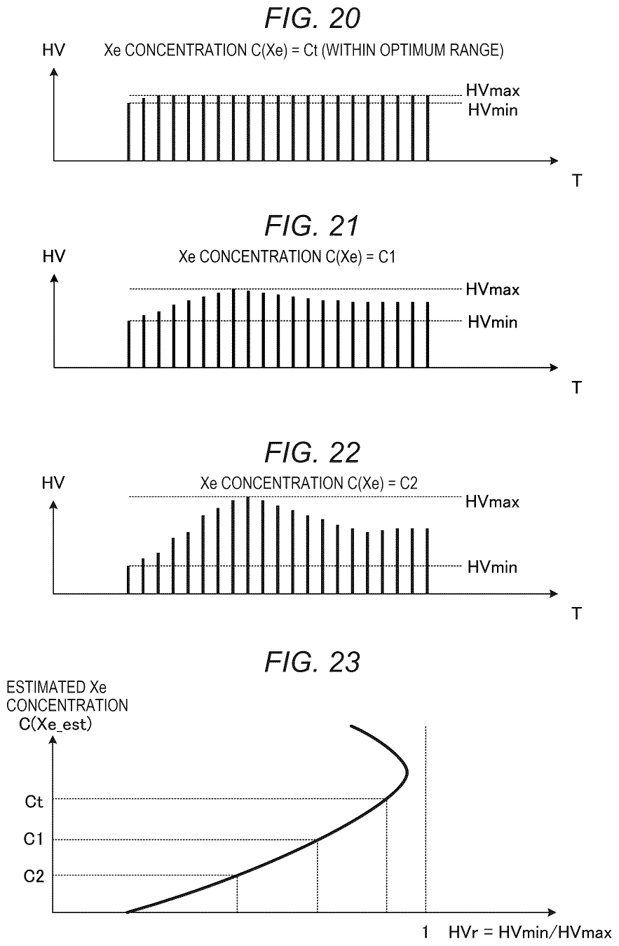

A second method for calculating the estimated xenon concentration C(Xe_est) from the laser performance will be described with reference to FIGS. 20 to 23. In S21 in FIG. 13, the estimated xenon concentration C(Xe_est) calculated by the second method may be used in place of the Xe concentration in the exhaust gas C(Xe_vent_n) described with reference to FIGS. 6 to 12.

FIGS. 20 to 22 show examples of changes over time T in a voltage HV having high-voltage pulses and applied to the discharge electrodes in the laser apparatus 30a. In the laser apparatus 30a, feedback control may be so performed on the voltage HV that the laser light has constant pulse energy E. In the feedback control, the stability of the voltage HV within the predetermined period described above may change in accordance with the state of the laser apparatus 30a.

FIG. 20 shows the voltage HV in the case where the xenon concentration Ct inside the laser chamber 10 falls within the optimum range. A ratio HVr of a minimum value HVmin to a maximum value HVmax of the voltage HV within the predetermined period described above is close to one, which means that the voltage HV is stable.

FIG. 21 shows the voltage HV in the case where the xenon concentration C1 inside the laser chamber 10 is outside the optimum range. The ratio HVr of the minimum value HVmin to the maximum value HVmax of the voltage HV within the predetermined period described above is decreased.

FIG. 22 shows the voltage HV in the case where the xenon concentration C2 inside the laser chamber 10 is outside the optimum range by a greater degree. The ratio HVr of the minimum value HVmin to the maximum value HVmax of the voltage HV within the predetermined period described above is further decreased.

FIG. 23 shows an example of a graph showing the relationship between the ratio HVr and the estimated xenon concentration C(Xe_est). When there is a fixed relationship between the ratio HVr and the xenon concentration inside the laser chamber 10, as shown in FIG. 23, the estimated xenon concentration C(Xe_est) can be calculated based on the relationship.

### 2.5 Laser Apparatus 30a Including OSC Laser Chamber 101 and AMP Laser Chamber 102

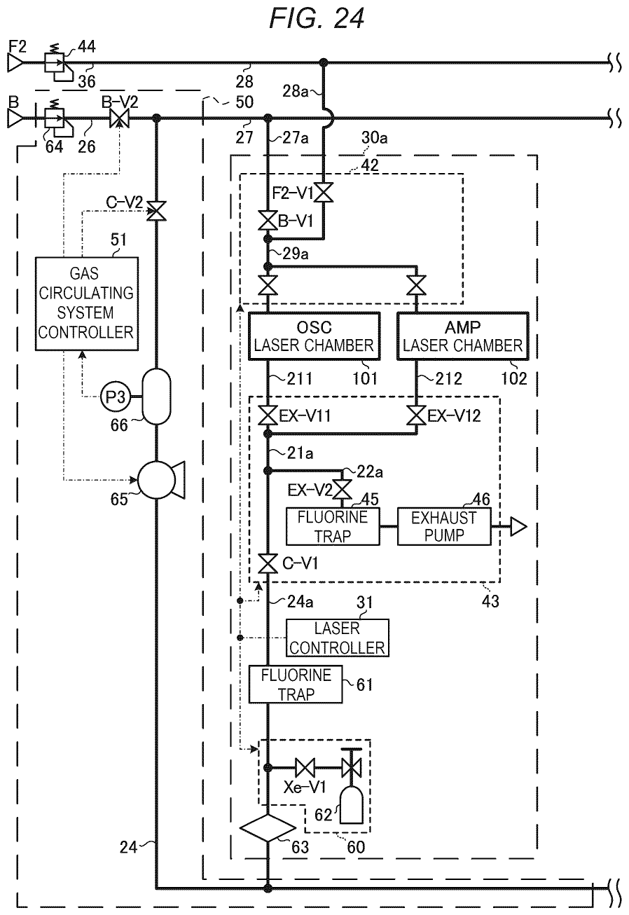

FIG. 24 schematically shows the configuration of a first variation of the first embodiment. FIG. 24 shows only one laser apparatus 30a, but does not show the other laser apparatus 30b. The laser apparatus 30a includes an OSC laser chamber 101 and an AMP laser chamber 102. The OSC laser chamber 101 is a laser chamber that outputs first laser light, and the first laser light enters the AMP laser chamber 102. The AMP laser chamber 102 is a laser chamber that amplifies the first laser light and outputs second laser light. The laser gas is supplied to each of the OSC laser chamber 101 and the AMP laser chamber 102, and the xenon gas concentrations inside the two laser chambers may differ from each other.

The pipe 29a branches off just before the OSC laser chamber 101 and the AMP laser chamber 102, and supplies the laser gas to each of the two laser chambers.

The OSC laser chamber 101 and the AMP laser chamber 102 are connected to a first exhaust path 211 and a second exhaust path 212, respectively. The first exhaust path 211 and the second exhaust path 212 are connected to the pipe 21a, and further connected to the exhaust pipe 24a.

A first valve EX-V11 and a second valve EX-V12 are disposed in the first exhaust path 211 and the second exhaust path 212, respectively. The first valve EX-V11 and the second valve EX-V12 are so controlled by the laser controller 31 that one of the two valves is opened with the other closed.

It is probable that the xenon concentration in the exhaust gas flowing through the pipe 21a and the exhaust pipe 24a when the first valve EX-V11 is opened differs from the xenon concentration in the exhaust gas flowing through the two pipes when the second valve EX-V12 is opened. In view of the circumstance described above, the laser controller 31 evaluates, based on information on the control of the first valve EX-V11 and the second valve EX-V12, whether the exhaust gas from the OSC laser chamber 101 or the exhaust gas from the AMP laser chamber 102 is flowing through the exhaust pipe 24a. Based on the result of the evaluation, the xenon adder 60 is so controlled that the additive gas corresponding to the Xe concentration in the exhaust gas from one of the laser chambers is added to the exhaust gas.

### 2.6 Laser Apparatus 30a Including Xenon Adder 60 Disposed Outside Enclosure

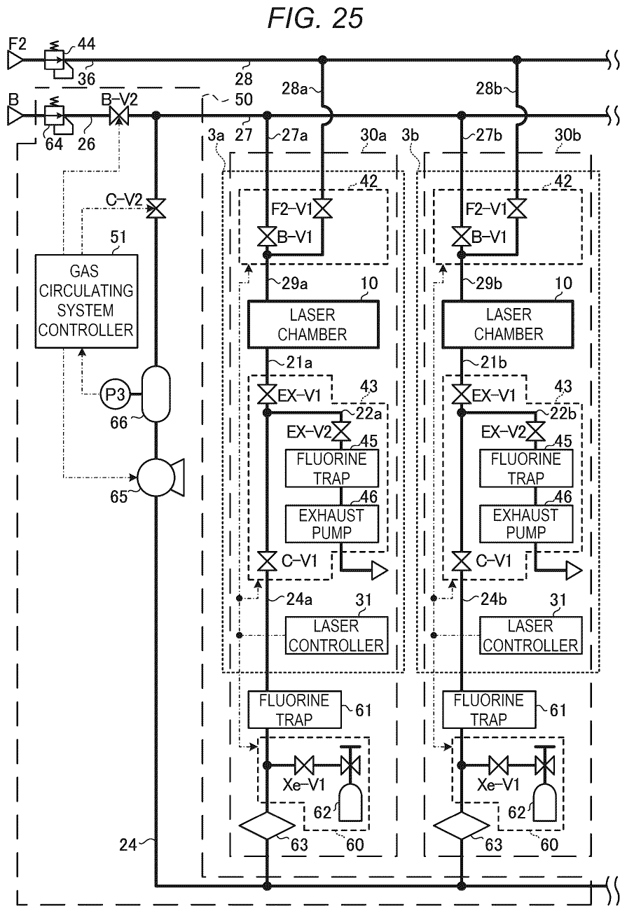

FIG. 25 schematically shows the configuration of a second variation of the first embodiment. In the laser apparatus 30a shown in FIG. 25, the laser chamber 10, the gas supplier 42, and the exhauster 43 are arranged inside a single laser enclosure 3a. The fluorine trap 61, the xenon adder 60, and the filter 63 provided in the laser apparatus 30a are all disposed outside the laser enclosure 3a.

According to the second variation, when the fluorine trap 61, the xenon adder 60, and the filter 63 are to be added to the laser apparatus 30a including none of the fluorine trap 61, the xenon adder 60, and the filter 63, there is no need to significantly modify the laser enclosure 3a.

### 2.7 Effects

(1) According to the first embodiment, the laser apparatus 30a includes the laser chamber 10, the exhaust pipe 24a, the fluorine trap 61, and the xenon adder 60.

The laser chamber 10 is connected to the gas circulating system 50 including the merging pipe 24, where the exhaust gases exhausted from the multiple laser apparatuses 30a and 30b including the laser apparatus 30a merge with each other, the gas circulating system 50 selecting one of the fresh inert gas containing xenon and the regenerated inert gas flowing through the merging pipe 24 and supplying the multiple laser apparatuses 30a and 30b with the selected gas.

The exhaust pipe 24a is connected to a point between the laser chamber 10 and the merging pipe 24, and is so configured that the exhaust gas exhausted from the laser chamber 10 flows toward the merging pipe 24.

The fluorine trap 61 is connected to a halfway point of the exhaust pipe 24a and removes at least fluorine from the exhaust gas exhausted from the laser chamber 10.

The xenon adder 60 is connected to a halfway point of the exhaust pipe 24a and adds the additive gas having a xenon concentration higher than that of the fresh inert gas to the exhaust gas exhausted from the laser chamber 10.

With the configuration described above, even when the exhaust gases from the laser chambers 10 have different xenon concentrations, the xenon adder 60 can compensate for the shortage of xenon in any of the exhaust gases in accordance with the xenon concentration in the exhaust gas. Therefore, the xenon concentration in the regenerated inert gas can be brought close to a desired xenon concentration.

(2) According to the first embodiment, the xenon adder 60 is located downstream from the fluorine trap 61 in the flow of the exhaust gas exhausted from the laser chamber 10.

Although some of the xenon may be removed by the fluorine trap 61, the amount of xenon to be added by the xenon adder 60 can be suppressed by adding xenon to the exhaust gas having passed through the fluorine trap 61.

(3) According to the first variation of the first embodiment, the laser apparatus 30a includes the OSC laser chamber 101 and the AMP laser chamber 102, which are connected to the exhaust pipe 24a via the first exhaust path 211 and the second exhaust path 212, respectively. The first valve EX-V11 and the second valve EX-V12 are disposed in the first exhaust path 211 and the second exhaust path 212, respectively, and are so controlled that one of the two valves is opened while the other is closed.

With the configuration described above, in the laser apparatus 30a including the two laser chambers, the first valve EX-V11 and the second valve EX-V12 are so controlled that the two laser chambers exhaust the exhaust gas one at a time, and the exhaust pipe 24a is shared by the two laser chambers, so that the xenon adder 60 can be shared by the two laser chambers.

(4) According to the first embodiment, the laser apparatus 30a includes the laser controller 31, which calculates the amount of additive gas V(Xe_add_cy) to be added to the exhaust gas with reference to the xenon concentration in the fresh inert gas C(Xe_cy).

With the configuration described above, since the amount of additive gas to be added to the exhaust gas V(Xe_add_cy) is calculated with reference to the xenon concentration in the fresh inert gas C(Xe_cy), there is no need to change the calculation of the xenon concentration in the laser chamber 10 based on whether the circulating gas or the fresh gas is supplied from the gas circulating system 50 to the laser chamber 10.

(5) According to the first embodiment, the valve C-V1 is disposed in the exhaust pipe 24a between the laser chamber 10 and the xenon adder 60. The laser controller 31 controls the valve C-V1 and the xenon adder 60 to alternately perform the following two kinds of operation: opening the valve C-V1 and then closing the valve C-V1; and causing the xenon adder 60 to add the additive gas to the exhaust gas exhausted from the laser chamber 10 by an amount smaller than or equal to half the amount of additive gas to be added to the exhaust gas V(Xe_add_cy).

With the configuration described above, the exhaust gas and the additive gas can be mixed with each other in the pipe.

(6) According to the first embodiment, the laser controller 31 calculates the estimated xenon concentration C(Xe_est) in the exhaust gas exhausted from the laser chamber 10 based on the laser performance of the laser apparatus 30a, and calculates the amount of additive gas to be added to the exhaust gas V(Xe_add_cy) based on the xenon concentration in the fresh inert gas C(Xe_cy) and the estimated xenon concentration C(Xe_est).

With the configuration described above, data on the laser performance can be used to calculate the xenon concentration excluding, for example, xenon lost in a chemical reaction with fluorine.

(7) According to the first embodiment, the laser controller 31 calculates the Xe concentration in the exhaust gas C(Xe_vent_n) exhausted from the laser chamber 10, and calculates the amount of additive gas to be added to the exhaust gas V(Xe_add_cy) based on the xenon concentration in the fresh inert gas C(Xe_cy) and the Xe concentration in the exhaust gas C(Xe_vent_n).

With the configuration described above, instead of using a result of measurement made by a gas analyzer, using a calculated value as the xenon concentration in the exhaust gas allows reduction in the manufacturing cost of the laser apparatus 30a.

(8) According to the first embodiment, the laser chamber 10 is connected to the fluorine-containing gas supply source F2. The laser controller 31 calculates the Xe concentration in the exhaust gas C(Xe_vent_n) based on the amounts of suppled fluorine-containing gas V(F_ini) and V(F_n) supplied from the fluorine-containing gas supply source F2 to the laser chamber 10, and one of the amount of fresh inert gas V(Ar_ini) and the amount of regenerated inert gas V(Ar_n) both supplied from the gas circulating system 50 to the laser chamber 10.

With the configuration described above, using data on the amounts of supplied gases allows accurate calculation of the xenon concentration C(Xe_vent_n) in the laser chamber.

As for the other points, the first embodiment is the same as Comparative Example.

3. Laser Apparatus 30a that Corrects Xenon Concentration and Calculates the Amount of Xe to be Added to the Exhaust Gas V(Xe_Add_Cy)

### 3.1 Xenon Addition Process

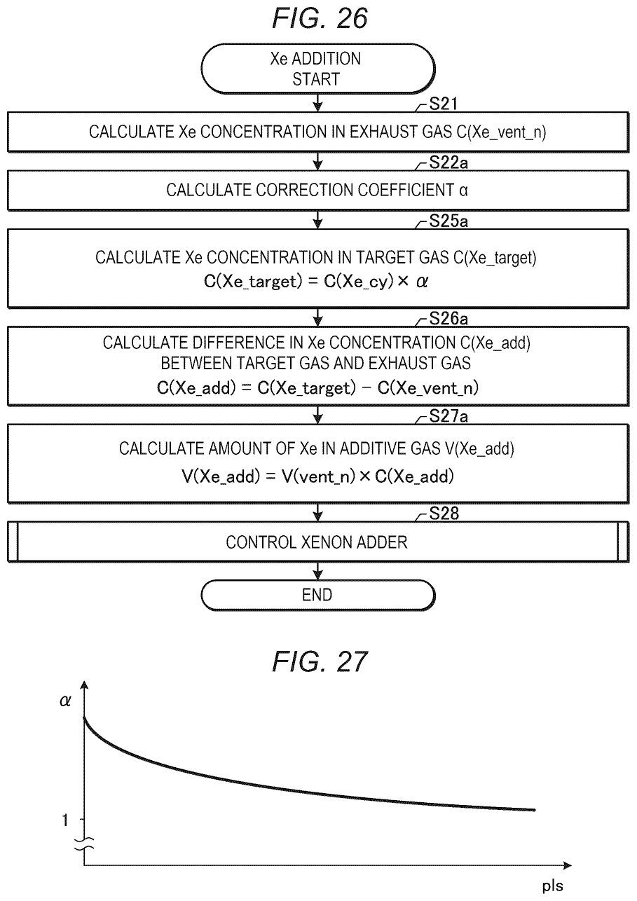

FIG. 26 is a flowchart showing a xenon addition process in a second embodiment. The first embodiment has been presented with reference to the case where the Xe concentration in the exhaust gas C(Xe_vent_n) is calculated from data on the entire history of the laser gas supply and exhaust operations, and the concentration of xenon actually contained in the exhaust gas may be lower than the Xe concentration in the exhaust gas C(Xe_vent_n) due to some factors. For example, xenon and fluorine may chemically react with each other to form xenon fluoride, which may be removed by the fluorine trap 61. In view of the circumstance described above, a correction coefficient α is calculated to overestimate the difference between a Xe concentration in a target gas C(Xe_target) to be achieved by adding the additive gas and the Xe concentration in the exhaust gas C(Xe_vent_n). The configuration of the laser system according to the second embodiment is the same as that according to the first embodiment.

The process in S21 is the same as that in FIG. 13.

In S22a, the laser controller 31 calculates the correction coefficient α. The calculation of the correction coefficient α will be described with reference to FIG. 27.

In S25a, the laser controller 31 calculates the Xe concentration in the target gas C(Xe_target) by using the following expression:

$$C ( Xe\_target ) = C ( Xe\_cy ) \times α$$

In S26a, the laser controller 31 calculates a difference in xenon concentration C(Xe_add) between the target gas and the exhaust gas by using the following expression:

$$C ( Xe\_add ) = C ( Xe\_target ) - C ( Xe\_vent \_n )$$

In S27a, the laser controller 31 calculates the amount of xenon in the additive gas V(Xe_add) by using the following expression in such a way that the xenon concentration in the exhaust gas approaches the Xe concentration in the target gas C(Xe_target).

$$V ( Xe\_add ) = V ( vent\_n ) \times C ( Xe\_add )$$

In S28, the laser controller 31 controls the xenon adder 60 to add the additive gas containing xenon by the amount of xenon V(Xe_add) to the exhaust gas. The process in S28 is the same as that in FIGS. 13 and 14.

After step S28, the laser controller 31 terminates the processes in the present flowchart.

FIG. 27 shows an example of the correction coefficient α. The correction coefficient α is set for each of the laser chambers 10. The correction coefficient α may be determined in accordance with the number of discharge pulses pls counted from the time when the laser chamber 10 is new. For example, the correction coefficient α may be stored in a memory that is not shown but is an element of the laser controller 31 in the form of table data in which the correction coefficient α is associated with the number of discharge pulses pls. The correction coefficient α may instead be stored in a memory in the form of a function of the number of discharge pulses pls.

The correction coefficient α is a value greater than one. As a result, the Xe concentration in the target gas C(Xe_target) obtained by multiplying the xenon concentration in the fresh inert gas C(Xe_cy) by the correction coefficient α becomes greater than the xenon concentration in the fresh inert gas C(Xe_cy). Therefore, the difference in xenon concentration C(Xe_add) between the Xe concentration in the target gas C(Xe_target) and the xenon concentration in the exhaust gas C(Xe_vent_n) becomes greater than the difference in xenon concentration C(Xe_add_n) between the xenon concentration in the fresh inert gas C(Xe_cy) and the xenon concentration in the exhaust gas C(Xe_vent_n), and the calculated amount of Xe to be added to the exhaust gas V(Xe_add_cy) is greater than that in FIG. 13.

### 3.2 Effects

(9) According to the second embodiment, the laser controller 31 calculates the amount of additive gas to be added to the exhaust gas V(Xe_add_cy) based on the xenon concentration in the fresh inert gas C(Xe_cy), the Xe concentration in the exhaust gas C(Xe_vent_n), and the correction coefficient α used to overestimate the difference C(Xe_add) between the xenon concentration in the target gas C(Xe_target) achieved by adding the additive gas to the exhaust gas exhausted from the laser chamber 10 and the Xe concentration in the exhaust gas C(Xe_vent_n) as compared with the difference C(Xe_add_n) between the xenon concentration in the fresh inert gas C(Xe_cy) and the Xe concentration in the exhaust gas C(Xe_vent_n).

With the configuration described above, the laser controller 31 can calculate the amount of additive gas to be added to the exhaust gas V(Xe_add_cy) by using the correction coefficient α in addition to the xenon concentration in the fresh inert gas C(Xe_cy) and the Xe concentration in the exhaust gas C(Xe_vent_n) in consideration of the shortage of xenon lost due, for example, to a chemical reaction between xenon and fluorine.

(10) According to the second embodiment, the laser controller 31 acquires the number of discharge pulses pls generated in the laser chamber 10, and accesses a storage that stores the relationship between the number of discharge pulses pls and the correction coefficient α to acquire the correction coefficient α.

With the configuration described above, the laser controller 31 can calculate the amount of additive gas to be added to the exhaust gas V(Xe_add_cy) more appropriately by determining the correction coefficient α in accordance with the number of discharge pulses pls generated in the laser chamber 10.

As for the other points, the second embodiment is the same as the first embodiment.

4. Laser Apparatus 30a that Updates Correction Coefficient α

### 4.1 Configuration

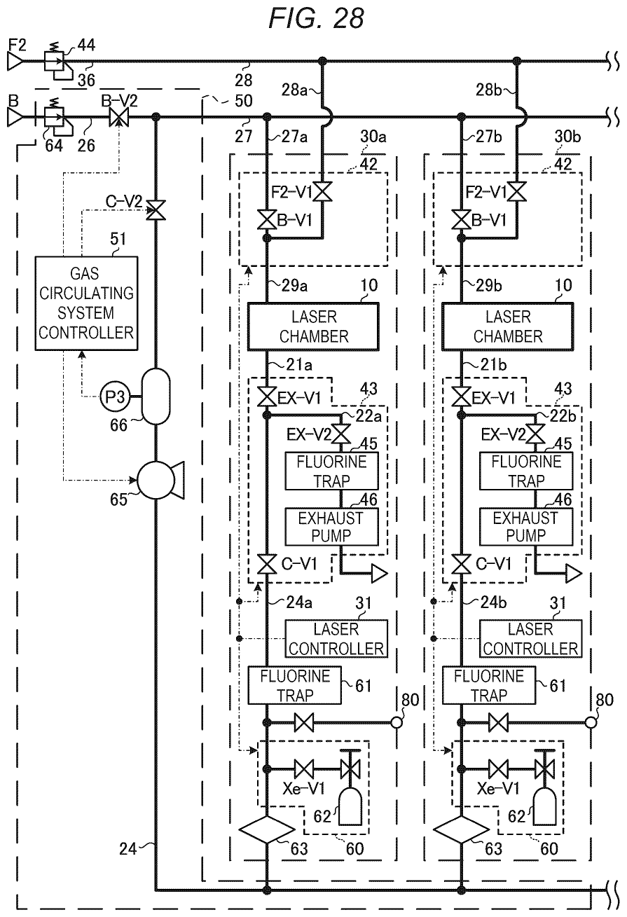

FIG. 28 schematically shows the configuration of a laser system according to a third embodiment. In the third embodiment, a sampling port 80, via which part of the exhaust gas can be extracted, is connected to each of the exhaust pipes 24a and 24b. The sampling port 80 is disposed, for example, at a position where the sampling port 80 is accessible from the outside of the enclosure of each of the laser apparatuses 30a and 30b that is not shown. A manual valve is disposed between each of the exhaust pipes 24a and 24b and the sampling port 80, and is normally closed but is opened when part of the exhaust gas is extracted.

A xenon concentration meter that is not shown can be connected to the sampling port 80. It is not necessary to provide each of the laser apparatuses 30a and 30b with the xenon concentration meter, but one xenon concentration meter can be interchangeably used by attaching the xenon concentration meter alternately to the laser apparatuses 30a and 30b.

It is desirable to connect the sampling port 80 to each of the exhaust pipes 24a and 24b between the laser chamber 10 and the xenon adder 60. A measured xenon concentration C(Xe_mes) in the exhaust gas before xenon is added can therefore be measured, so that the shortage of xenon can be accurately estimated.

It is desirable to connect the sampling port 80 to each of the exhaust pipes 24a and 24b between the fluorine trap 61 and the merging pipe 24. The concentration of the xenon gas excluding the xenon fluoride produced by the chemical reaction with fluorine can thus be measured.

### 4.2 Xenon Addition Process

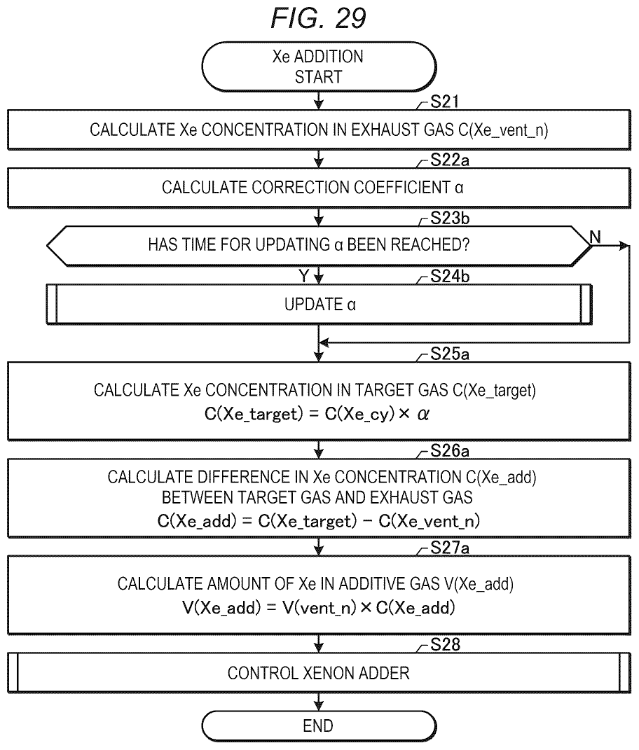

FIG. 29 is a flowchart showing a xenon addition process in the third embodiment. In the third embodiment, the correction coefficient α calculated in the second embodiment is updated based on the measured xenon concentration C(Xe_mes) in the exhaust gas. The correction coefficient α is updated less frequently than the calculation of the amount of xenon to be added to the exhaust gas V(Xe_add_cy) using the correction coefficient α.

The processes in S21 and S22a are the same as those in FIG. 26.

In S23b, the laser controller 31 evaluates whether the time for updating the correction coefficient α has been reached. The correction coefficient α may be updated, for example, once a day, or may be updated whenever maintenance of the laser apparatus 30a or 30b is performed. When the time for updating the correction coefficient α has been reached (YES in S23b), the laser controller 31 proceeds to the process in S24b.

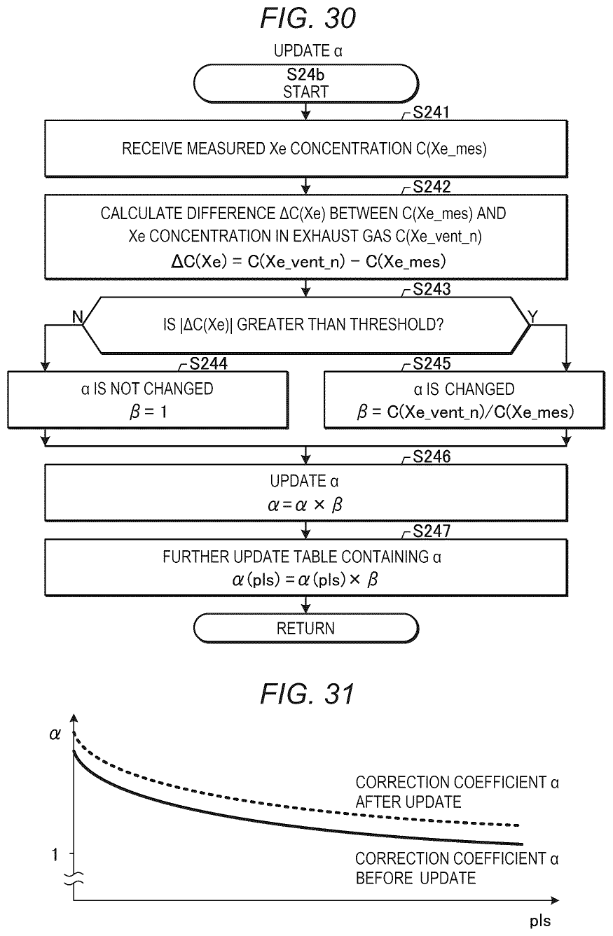

In S24b, the laser controller 31 updates the correction coefficient α by using the measured xenon concentration C(Xe_mes). S24b will be described in detail with reference to FIGS. 30 and 31. After S24b, the laser controller 31 proceeds to the process in S25a.

When the time for updating the correction coefficient α has not been reached (NO in S23b), the laser controller 31 proceeds to the process in S25a.

The processes in S25a to S28 are the same as those in FIG. 26.

### 4.3 Updating Correction Coefficient α

FIG. 30 is a flowchart showing how to update the correction coefficient α in detail. The processes shown in FIG. 30 correspond to the subroutine S24b shown in FIG. 29

In S241, the laser controller 31 receives the measured xenon concentration in the exhaust gas C(Xe_mes). The measured xenon concentration C(Xe_mes) may be received from the xenon concentration meter, or may be input by an operator who operates the xenon concentration meter.

In S242, the laser controller 31 calculates a difference ΔC(Xe) between the measured xenon concentration C(Xe_mes) and the Xe concentration in the exhaust gas C(Xe_vent_n) by using the following expression:

$$Δ C ( X e ) = C ( Xe\_vent \_n ) - C ( Xe\_mes )$$

In S243, the laser controller 31 evaluates whether the absolute value of the difference ΔC(Xe) is greater than a threshold. When the absolute value of the difference ΔC(Xe) is smaller than or equal to the threshold (NO in S243), the laser controller 31 proceeds to the process in S244. When the absolute value of the difference ΔC(Xe) is greater than the threshold (YES in S243), the laser controller 31 proceeds to the process in S245.

In S244, the laser controller 31 sets an update parameter β used to update the correction coefficient α to one. In this case, the correction coefficient α is changed neither in S246 nor S247, which will be described later. When the difference ΔC(Xe) is very small, the correction coefficient α is not changed, so that otherwise unstable control is avoided.

In S245, the laser controller 31 sets the update parameter β used to update the correction coefficient α by using the following expression. In this case, the correction coefficient α is changed in S246 and S247, which will be described later.

$$β = C ( Xe\_vent \_n ) / C ( Xe\_mes )$$

After S244 or S245, the laser controller 31 proceeds to the process in S246. In S246, the laser controller 31 updates the correction coefficient α by using the following expression:

$$α = α \times β$$

Furthermore, in S247, the laser controller 31 updates the table data on the correction coefficient α by using the following expression:

$$α ( p l s ) = α ( p l s ) \times β$$

where α(pls) is a correction coefficient associated with the number of discharge pulses pls.

After S247, the laser controller 31 terminates the processes in the present flowchart and returns to the processes shown in FIG. 29.

FIG. 31 shows an example of the correction coefficient α before and after the update. For example, when the correction coefficient α is stored in a memory in the form of the table data associated with the number of discharge pulses pls, the correction coefficient α is updated for each value of the number of discharge pulses pls. When the correction coefficient α is stored in a memory in the form of a function of the number of discharge pulses pls, the correction coefficient α is updated by transforming the function.

The third embodiment has been described with reference to the case where the correction coefficient α is updated by using the measured xenon concentration C(Xe_mes), but not necessarily in the present disclosure. As described with reference to FIGS. 16 to 23, the estimated xenon concentration C(Xe_est) inside the laser chamber 10 can also be calculated from the laser performance. The correction coefficient α may be updated by using the estimated xenon concentration C(Xe_est).

### 4.4 Effects

(11) According to the third embodiment, the laser controller 31 calculates the estimated xenon concentration C(Xe_est) in the exhaust gas exhausted from the laser chamber 10 based on the laser performance of the laser apparatus 30a, and updates the correction coefficient α based on the estimated xenon concentration C(Xe_est).

With the configuration described above, the laser controller 31 can update the correction coefficient α to an appropriate value by using the estimated xenon concentration C(Xe_est) calculated by using the data on the laser performance.

(12) According to the third embodiment, the laser controller 31 acquires the measured xenon concentration C(Xe_mes) in either the exhaust gas discharged from the laser chamber 10 or the regenerated inert gas, and updates the correction coefficient α based on the measured xenon concentration C(Xe_mes).

With the configuration described above, the laser controller 31 can revise the correction coefficient α to an appropriate value by using the measured xenon concentration C(Xe_mes) having been actually measured.

(13) According to the third embodiment, the sampling port 80 provided in the laser apparatus 30a is connected to the exhaust pipe 24a and configured to be connectable to the xenon concentration meter.

With the configuration described above, even when each laser apparatus 30a is not provided with the xenon concentration meter, the xenon concentration meter can be connected to the sampling port 80 when necessary to determine the measured xenon concentration C(Xe_mes).

(14) According to the third embodiment, the laser controller 31 receives the measured xenon concentration C(Xe_mes) at a first frequency, updates the correction coefficient α, and calculates the amount of additive gas to be added to the exhaust gas V(Xe_add_cy) based on the correction coefficient α at a second frequency higher than the first frequency.

With the configuration described above, the laser controller 31, which receives the measured xenon concentration C(Xe_mes) at the first frequency lower than the second frequency, at which the amount of additive gas to be added to the exhaust gas V(Xe_add_cy) is calculated, can lower the frequency of use of the xenon concentration meter to lower the frequency of replacement of consumables such as the column of the xenon concentration meter.

(15) According to the third embodiment, the laser controller 31 is configured to be able to access the storage that stores the relationship between the number of discharge pulses pls generated in the laser chamber 10 and the correction coefficient α. The laser controller 31 updates the relationship based on the measured xenon concentration C(Xe_mes), and calculates the amount of additive gas to be added to the exhaust gas V(Xe_add_cy) based on the correction coefficient α obtained from the updated relationship.

With the configuration described above, the laser controller 31 can calculate the amount of additive gas to be added to the exhaust gas V(Xe_add_cy) more appropriately by updating the correction coefficient α according to the number of discharge pulses pls generated in the laser chamber 10 based on the measured xenon concentration C(Xe_mes).

As for the other points, the third embodiment is the same as the second embodiment.

5. Laser System that Updates Correction Coefficient α by Using Measured Xenon Concentration C(Xe_Mes) in Regenerated Inert Gas

### 5.1 Configuration

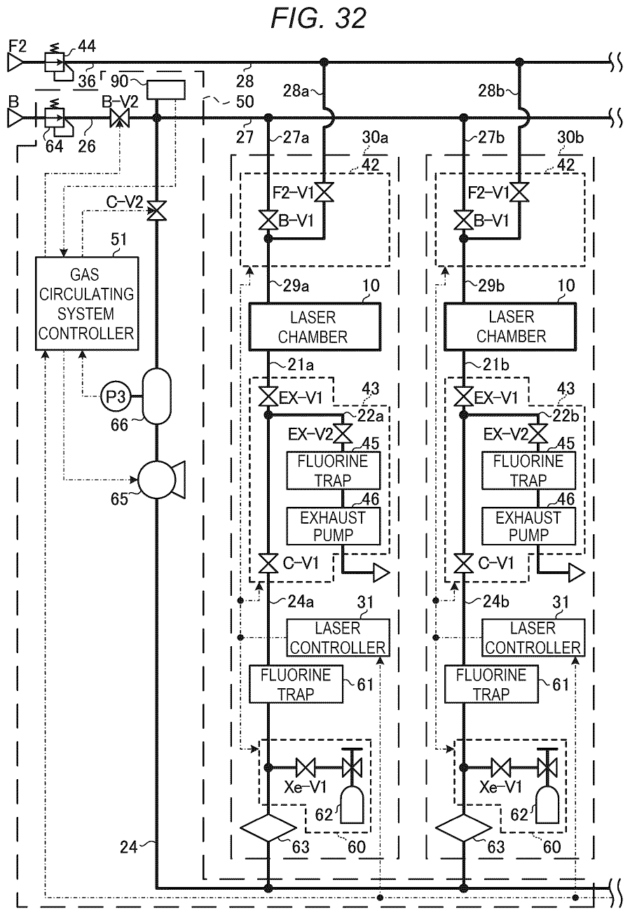

FIG. 32 schematically shows the configuration of a laser system according to a fourth embodiment. In the fourth embodiment, a xenon concentration meter 90 is disposed at a position where the merging pipe 24, through which the regenerated inert gas flows, and the fresh inert gas pipe 26, through which the fresh inert gas flows, merge with each other. The xenon concentration meter 90 includes, for example, a gas chromatograph mass spectrometer (GS-MS).

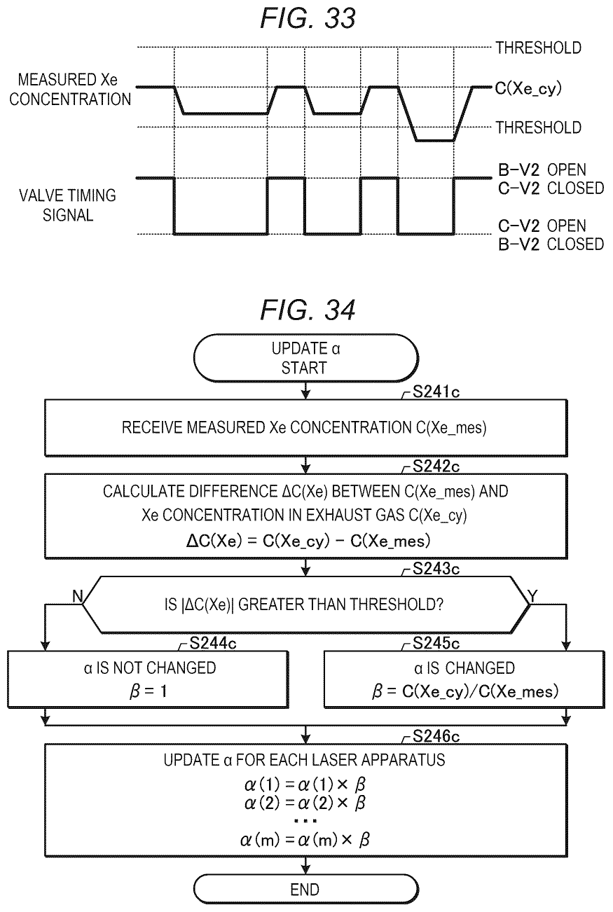

FIG. 33 is a timing chart showing how the xenon concentration meter 90 measures the measured xenon concentration C(Xe_mes) in the regenerated inert gas. The valve C-V2 disposed in the merging pipe 24 and the valve B-V2 disposed in the fresh inert gas pipe 26 are so controlled that one of the two valves is closed and the other is opened so that both valves are not open. When the valve B-V2 is open, the xenon concentration meter 90 measures the xenon concentration in the fresh inert gas C(Xe_cy). When the valve C-V2 is open, the xenon concentration meter 90 measures the xenon concentration in the regenerated inert gas. The xenon concentration in the fresh inert gas C(Xe_cy) is always almost constant. Using the fresh inert gas as a reference gas and using the xenon concentration in the fresh inert gas C(Xe_cy) as a reference allow accurate measurement of the measured xenon concentration C(Xe_mes) in the regenerated inert gas.

The xenon concentration meter 90 may instead be disposed in the inert gas pipe 27 extending from the position where the merging pipe 24 and the fresh inert gas pipe 26 merge with each other to the first branch point where the inert gas pipe 27 branches to the laser apparatus 30a. When the position where the merging pipe 24 and the fresh inert gas pipe 26 merge with each other is separate from the xenon concentration meter 90 by a large distance, it may become difficult to distinguish the xenon concentration in the regenerated inert gas measured with the xenon concentration meter 90 from the xenon concentration in the fresh inert gas measured therewith. A flow rate meter or a mass flow controller including a flow rate meter and a flow rate control valve may be disposed in each of the merging pipe 24 and the fresh inert gas pipe 26 to make the distinction described above from the history of the flow rates measured with the flow rate meter or the mass flow controller. The distance from the position where the merging pipe 24 and the fresh inert gas pipe 26 merge with each other to the xenon concentration meter 90 is desirably greater than or equal to 0 m but smaller than or equal to 1 m.

### 5.2 Updating Correction Coefficient α

FIG. 34 is a flowchart showing how to update the correction coefficient α in the fourth embodiment. In the fourth embodiment, the laser controllers 31 of the laser apparatuses 30a and 30b each individually calculate the correction coefficient α, and use the calculated correction coefficient α to calculate the amount of xenon to be added to the exhaust gas V(Xe_add_cy), as in FIG. 26. The update of the correction coefficient α based on the measured xenon concentration C(Xe_mes) is, however, not individually performed by the laser controllers 31 of the laser apparatuses 30a and 30b, but is instead collectively performed by the gas circulating system controller 51 in accordance with the procedure shown in FIG. 34. The update of the correction coefficient α shown in FIG. 34 is performed, for example, once a day, which is less frequently than the frequency at which the amount of xenon to be added to the exhaust gas V(Xe_add_cy) using the processes in FIG. 26 is calculated.

In S241c, the gas circulating system controller 51 receives the measured xenon concentration C(Xe_mes) in the regenerated inert gas from the xenon concentration meter 90.

In S242c, the gas circulating system controller 51 calculates the difference ΔC(Xe) between the measured xenon concentration C(Xe_mes) in the regenerated inert gas and the xenon concentration C(Xe_cy) in the fresh inert gas by using the following expression:

$$Δ C ( X e ) = C ( Xe\_cy ) - C ( Xe\_mes )$$

In S243c, the gas circulating system controller 51 evaluates whether the absolute value of the difference ΔC(Xe) is greater than the threshold. When the absolute value of the difference ΔC(Xe) is smaller than or equal to the threshold (NO in S243c), the gas circulating system controller 51 proceeds to the process in S244c. When the absolute value of the difference ΔC(Xe) is greater than the threshold (YES in S243c), the gas circulating system controller 51 proceeds to the process in S245c.

In S244c, the gas circulating system controller 51 sets the update parameter β used to update the correction coefficient α to one. In this case, the correction coefficient α is not changed in S246c, which will be described later. When the difference ΔC(Xe) is very small, the correction coefficient α is not changed, so that otherwise unstable control is avoided.

In S245c, the gas circulating system controller 51 sets the update parameter β used to update the correction coefficient α to a value determined by the following expression. In this case, the correction coefficient α is changed in S246c, which will be described later.

$$β = C ( Xe\_cy ) / C ( Xe\_mes )$$

After S244c or S245c, the gas circulating system controller 51 proceeds to the process in S246c. In S246c, the gas circulating system controller 51 updates the correction coefficient α for each laser apparatus by using the following expressions:

$$α ( 1 ) = α ( 1 ) \times β \\ α ( 2 ) = α ( 2 ) \times β \\ … \\ α ( m ) = α ( m ) \times β$$

In the expressions, m is the number of laser apparatuses connected to the gas circulating system 50. The coefficients α(1), α(2), . . . , α(m) are correction coefficients for the first to m-th laser apparatuses.

After step S246c, the gas circulating system controller 51 terminates the processes in the present flowchart.

### 5.3 Effects

(16) According to the fourth embodiment, the laser system includes the multiple laser apparatuses 30a and 30b and the gas circulating system 50.

The gas circulating system 50 includes the merging pipe 24, where the exhaust gases exhausted from the multiple laser apparatuses 30a and 30b merge with each other, selects one of the fresh inert gas containing xenon and the regenerated inert gas flowing through the merging pipe 24, and supplies the multiple laser apparatuses 30a and 30b with the selected gas.

The multiple laser apparatuses 30a and 30b each include the laser chamber 10, the exhaust pipe 24a or 24b, the fluorine trap 61, and the xenon adder 60.

The laser chamber 10 is connected to the gas circulating system 50.

The exhaust pipe 24a or 24b is connected to and between the laser chamber 10 and the merging pipe 24, and is so configured that the exhaust gas exhausted from the laser chamber 10 flows toward the merging pipe 24.

The fluorine trap 61 is connected to a halfway point of the exhaust pipe 24a or 24b and removes at least fluorine from the exhaust gas exhausted from the laser chamber 10.

The xenon adder 60 is connected to a halfway point of the exhaust pipe 24a or 24b and adds the additive gas having a xenon concentration higher than that of the fresh inert gas to the exhaust gas exhausted from the laser chamber 10.

With the configuration described above, even when the exhaust gases from the laser chambers 10 have different xenon concentrations, the xenon adder 60 can compensate for the shortage of xenon in any of the exhaust gases in accordance with the xenon concentration in the exhaust gas. Therefore, the xenon concentration in the regenerated inert gas can be brought close to a desired xenon concentration.

(17) According to the fourth embodiment, the laser system includes the gas circulating system controller 51, which calculates the amount of additive gas to be added to the exhaust gas V(Xe_add_cy), and the multiple laser apparatuses 30a and 30b are connected to the fluorine-containing gas supply source F2.

The gas circulating system controller 51 calculates the Xe concentration in the exhaust gas C(Xe_vent_n) exhausted from the laser chamber 10 based on the amounts of suppled fluorine-containing gas V(F_ini) and V(F_n) supplied from the fluorine-containing gas supply source F2 to the laser chamber 10, and one of the amount of fresh inert gas V(Ar_ini) and the amount of regenerated inert gas V(Ar_n) both supplied from the gas circulating system 50 to the laser chamber 10. The gas circulating system controller 51 calculates the amount of additive gas to be added to the exhaust gas V(Xe_add_cy) based on the xenon concentration in the fresh inert gas C(Xe_cy), the Xe concentration in the exhaust gas C(Xe_vent_n), and the correction coefficient α used to overestimate the difference C(Xe_add) between the xenon concentration in the target gas C(Xe_target) achieved by adding the additive gas to the exhaust gas exhausted from the laser chamber 10 and the Xe concentration in the exhaust gas C(Xe_vent_n) as compared with the difference C(Xe_add_n) between the xenon concentration in the fresh inert gas C(Xe_cy) and the Xe concentration in the exhaust gas C(Xe_vent_n).

With the configuration described above, the laser controller 31 can calculate the amount of additive gas to be added to the exhaust gas V(Xe_add_cy) by using the correction coefficient α in addition to the xenon concentration in the fresh inert gas C(Xe_cy) and the Xe concentration in the exhaust gas C(Xe_vent_n) in consideration of the shortage of xenon lost due, for example, to a chemical reaction between xenon and fluorine.

(18) According to the fourth embodiment, the gas circulating system 50 includes the inert gas pipe 27, where the fresh inert gas and the regenerated inert gas merge with each other and the gases branch to the multiple laser apparatuses 30a and 30b, and the xenon concentration meter 90, which is disposed between the point where the fresh inert gas and the regenerated inert gas merge with each other and the branching point where the inert gas pipe 27 branches to the multiple laser apparatuses 30a and 30b. The gas circulating system controller 51 updates the correction coefficient α based on the measured xenon concentration C(Xe_mes) measured with the xenon concentration meter 90.

With the configuration described above, the laser controller 31 can revise the correction coefficient α to an appropriate value by using the measured xenon concentration C(Xe_mes) having been actually measured.

(19) According to the fourth embodiment, the xenon concentration meter 90 measures the measured xenon concentration C(Xe_mes) by using the fresh inert gas as the reference gas.

With the configuration described above, the fourth embodiment eliminates the need for the xenon concentration meter 90 to include an individual reference gas supply source, and allows the xenon concentration in the regenerated inert gas to be closer to the xenon concentration in the fresh inert gas C(Xe_cy).

As for the other points, the fourth embodiment is the same as the second embodiment.

### 6. Others

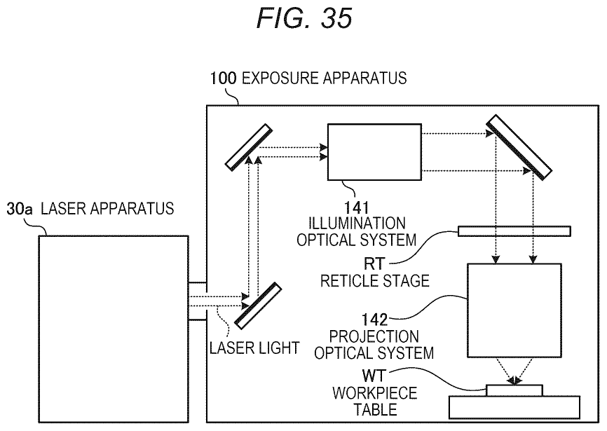

FIG. 35 schematically shows the configuration of an exposure apparatus 100 connected to the laser apparatus 30a. The laser apparatus 30a generates the laser light and outputs the laser light to the exposure apparatus 100, as described above.

In FIG. 35, the exposure apparatus 100 includes an illumination optical system 141 and a projection optical system 142. The illumination optical system 141 illuminates a reticle pattern of a reticle at a reticle stage RT with the laser light having entered the illumination optical system 141 from the laser apparatus 30a. The projection optical system 142 performs reduction projection on the laser light having passed through the reticle to bring the laser light into focus on a workpiece that is not shown but is placed on a workpiece table WT. The workpiece is a photosensitive substrate onto which a photoresist has been applied, such as a semiconductor wafer. The exposure apparatus 100 translates the reticle stage RT and the workpiece table WT in synchronization with each other to expose the workpiece to the laser light having reflected the reticle pattern. Electronic devices can be manufactured by transferring device patterns onto the semiconductor wafer in the exposure step described above.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A laser apparatus comprising:
a laser chamber connected to a gas circulating system including a merging pipe where exhaust gases exhausted from multiple laser apparatuses including the laser apparatus merge with each other, the gas circulating system being configured to select one of a fresh gas containing xenon and a circulating gas flowing through the merging pipe and supply the multiple laser apparatuses with the selected gas;
an exhaust pipe which is connected to and between the laser chamber and the merging pipe, and through which the exhaust gas exhausted from the laser chamber flows toward the merging pipe;
a fluorine trap connected to a halfway point of the exhaust pipe and configured to remove at least fluorine from the exhaust gas exhausted from the laser chamber; and
a xenon adder connected to a halfway point of the exhaust pipe and configured to add an additive gas having a xenon concentration higher than a xenon concentration in the fresh gas to the exhaust gas exhausted from the laser chamber.

2. The laser apparatus according to claim 1, wherein
the xenon adder is located downstream from the fluorine trap in a flow of the exhaust gas discharged from the laser chamber.

3. The laser apparatus according to claim 1, comprising
two laser chambers including the laser chamber,
wherein the two laser chambers are connected to the exhaust pipe via first and second exhaust paths, respectively, and
a first valve and a second valve are disposed in the first and second exhaust paths, respectively, and the first and second valves are so controlled that one of the valves is opened with the other closed.

4. The laser apparatus according to claim 1, further comprising
a processor configured to calculate an amount of the additive gas to be added with respect to the xenon concentration in the fresh gas.

5. The laser apparatus according to claim 4, wherein
a third valve is disposed in the exhaust pipe between the laser chamber and the xenon adder, and
the processor is configured to control the third valve and the xenon adder to alternately perform two kinds of operation: opening the third valve and then closing the third valve; and causing the xenon adder to add the additive gas to the exhaust gas exhausted from the laser chamber by an amount smaller than or equal to half the amount of the additive gas to be added.

6. The laser chamber according to claim 4, wherein
the processor is configured to
calculate an estimated xenon concentration in the exhaust gas discharged from the laser chamber based on laser performance of the laser apparatus, and
calculate the amount of the additive gas to be added based on the xenon concentration in the fresh gas and the estimated xenon concentration.

7. The laser apparatus according to claim 4, wherein
the processor is configured to
calculate a calculated xenon concentration in the exhaust gas discharged from the laser chamber, and
calculate the amount of the additive gas to be added based on the xenon concentration in the fresh gas and the calculated xenon concentration.

8. The laser apparatus according to claim 7, wherein
the laser chamber is connected to a fluorine-containing gas supply source, and
the processor is configured to calculate the calculated xenon concentration based on an amount of supplied fluorine-containing gas supplied from the fluorine-containing gas supply source to the laser chamber and an amount of one of the supplied fresh gas and the circulating gas supplied from the gas circulating system to the laser chamber.

9. The laser apparatus according to claim 8, wherein
the processor is configured to calculate the amount of the additive gas to be added based on
the xenon concentration in the fresh gas,
the calculated xenon concentration, and
a correction coefficient used to overestimate a difference between a xenon concentration in a target gas achieved by adding the additive gas to the exhaust gas exhausted from the laser chamber and the calculated xenon concentration as compared with a difference between the xenon concentration in the fresh gas and the calculated xenon concentration.

10. The laser apparatus according to claim 9, wherein
the processor is configured to
acquire the number of discharge pulses generated in the laser chamber, and
access a storage configured to store a relationship between the number of discharge pulses and the correction coefficient to acquire the correction coefficient.

11. The laser apparatus according to claim 9, wherein
the processor is configured to
calculate an estimated xenon concentration in the exhaust gas exhausted from the laser chamber based on laser performance of the laser apparatus, and
update the correction coefficient based on the estimated xenon concentration.

12. The laser apparatus according to claim 9, wherein
the processor is configured to
acquire a measured xenon concentration in either the exhaust gas exhausted from the laser chamber or the circulating gas, and
update the correction coefficient based on the measured xenon concentration.

13. The laser apparatus according to claim 12, further comprising
a sampling port connected to the exhaust pipe and configured to connect a xenon concentration meter.

14. The laser apparatus according to claim 12, wherein
the processor is configured to
receive the measured xenon concentration at a first frequency and update the correction coefficient, and
calculate the amount of the additive gas to be added based on the correction coefficient at a second frequency higher than the first frequency.

15. The laser apparatus according to claim 12, wherein
the processor is configured to
access a storage configured to store a relationship between the number of discharge pulses generated in the laser chamber and the correction coefficient,
update the relationship based on the measured xenon concentration, and
calculate the amount of the additive gas to be added based on the correction coefficient obtained from the updated relationship.

16. A laser system comprising:
multiple laser apparatuses; and
a gas circulating system including a merging pipe where exhaust gases exhausted from the multiple laser apparatuses merge with each other, the gas circulating system being configured to select one of a fresh gas containing xenon and a circulating gas flowing through the merging pipe and supply the multiple laser apparatuses with the selected gas,
the multiple laser apparatuses each including
a laser chamber connected to the gas circulating system,
an exhaust pipe which is connected to and between the laser chamber and the merging pipe, and through which the exhaust gas exhausted from the laser chamber flows toward the merging pipe;
a fluorine trap connected to a halfway point of the exhaust pipe and configured to remove at least fluorine from the exhaust gas exhausted from the laser chamber; and
a xenon adder connected to a halfway point of the exhaust pipe and configured to add an additive gas having a xenon concentration higher than a xenon concentration in the fresh gas to the exhaust gas exhausted from the laser chamber.

17. The laser system according to claim 16, further comprising
a processor configured to calculate an amount of the additive gas to be added,
wherein the multiple laser apparatuses are connected to a fluorine-containing gas supply source,
the processor is configured to
calculate a calculated xenon concentration in the exhaust gas exhausted from the laser chamber based on an amount of supplied fluorine-containing gas supplied from the fluorine-containing gas supply source to the laser chamber and an amount of one of the supplied fresh gas and circulating gas supplied from the gas circulating system to the laser chamber, and
calculate the amount of the additive gas to be added based on the xenon concentration in the fresh gas, the calculated xenon concentration, and a correction coefficient used to overestimate a difference between a xenon concentration in a target gas achieved by adding the additive gas to the exhaust gas exhausted from the laser chamber and the calculated xenon concentration as compared with a difference between the xenon concentration in the fresh gas and the calculated xenon concentration.

18. The laser system according to claim 17,
wherein the gas circulating system includes
an inert gas pipe where the fresh gas and the circulating gas merge with each other and branch to the multiple laser apparatuses, and
a xenon concentration meter disposed between a point where the fresh gas and the circulating gas merge with each other and a branching point where the inert gas pipe branches to the multiple laser apparatuses, and
the processor is configured to update the correction coefficient based on a measured xenon concentration measured with the xenon concentration meter.

19. The laser system according to claim 18, wherein
the xenon concentration meter is configured to measure the measured xenon concentration by using the fresh gas as a reference gas.

20. A method for manufacturing electronic devices, the method comprising:
generating laser light by using a laser apparatus that is one of multiple laser apparatuses;
outputting the laser light to an exposure apparatus; and
exposing a photosensitive substrate to the laser light in the exposure apparatus to manufacture the electronic devices,
the laser apparatus including
a laser chamber connected to a gas circulating system including a merging pipe where exhaust gases exhausted from the multiple laser apparatuses merge with each other, the gas circulating system being configured to select one of a fresh gas containing xenon and a circulating gas flowing through the merging pipe and supply the multiple laser apparatuses with the selected gas,
an exhaust pipe which is connected to and between the laser chamber and the merging pipe, and through which the exhaust gas exhausted from the laser chamber flows toward the merging pipe,
a fluorine trap connected to a halfway point of the exhaust pipe and configured to remove at least fluorine from the exhaust gas exhausted from the laser chamber, and
a xenon adder connected to a halfway point of the exhaust pipe and configured to add an additive gas having a xenon concentration higher than a xenon concentration in the fresh gas to the exhaust gas exhausted from the laser chamber.
